(19) United States
(12) Patent Application Publication
(10) Pub. No.: US 2026/0043135 A1
(43) Pub. Date: Feb. 12, 2026

(54) INDEPENDENTLY ADJUSTABLE FLOWPATH CONDUCTANCE IN MULTI-STATION SEMICONDUCTOR PROCESSING

(71) Applicant: Lam Research Corporation, Fremont, CA (US)

(72) Inventors: Michael Philip Roberts, Tigard, OR (US); Brian Williams, Beaverton, OR (US); Francisco J. Juarez, West Linn, OR (US); Rachel E. Batzer, Tigard, OR (US); Ramesh Chandrasekharan, Lake Oswego, OR (US); Richard Phillips, Spanish Fork, UT (US); Nuoya Yang, Frisco, TX (US); Joseph L. Womack, Tigard, OR (US); Ming Li, West Linn, OR (US); Jun Qian, Sherwood, OR (US); Tu Hong, Lake Oswego, OR (US); Sky Mullenaux, Tigard, OR (US)

(21) Appl. No.: 19/364,841

(22) Filed: Oct. 21, 2025

Related U.S. Application Data
(62) Division of application No. 17/595,966.
(60) Provisional application No. 62/858,570, filed on Jun. 7, 2019.

(51) Int. Cl. C23C 16/455; C23C 16/52; H01L 21/67

(52) U.S. Cl. CPC C23C 16/45544; C23C 16/45536; C23C 16/45553; C23C 16/45565; C23C 16/4557; C23C 16/52; H01L 21/67017; H01L 21/6719

(57) ABSTRACT

Methods and apparatuses are provided herein for independently adjusting flowpath conductance. One multi-station processing apparatus may include a processing chamber, a plurality of process stations in the processing chamber that each include a showerhead having a gas inlet, and a gas delivery system including a junction point and a plurality of flowpaths, in which each flowpath includes a flow element, includes a temperature control unit that is thermally connected with the flow element and that is controllable to change the temperature of that flow element, and fluidically connects one corresponding gas inlet of a process station to the junction point such that each process station of the plurality of process stations is fluidically connected to the junction point by a different flowpath.

### INCORPORATION BY REFERENCE

An Application Data Sheet is filed concurrently with this specification as part of the present application. Each application that the present application claims benefit of or priority to as identified in the concurrently filed Application Data Sheet is incorporated by reference herein in its entirety and for all purposes.

### BACKGROUND

During semiconductor processing operations, a substrate is typically supported on a pedestal within a processing chamber and process gases are flowed into the chamber in order to deposit one or more layers of material onto the substrate. In commercial scale manufacturing, each substrate, or wafer, contains many copies of a particular semiconductor device being manufactured, and many substrates are required to achieve the required volumes of devices. The commercial viability of a semiconductor processing operation depends in large part upon within-wafer uniformity and wafer-to-wafer repeatability of the process conditions. Accordingly, efforts are made to ensure that each portion of a given wafer and each wafer processed are exposed to the same processing conditions. Variation in the processing conditions and the semiconductor processing tool can cause variations in deposition conditions resulting in unacceptable variation in the overall process and product. Techniques and apparatus to minimize process variation are required.

Background and contextual descriptions contained herein are provided solely for the purpose of generally presenting the context of the disclosure. Much of this disclosure presents work of the inventors, and simply because such work is described in the background section or presented as context elsewhere herein does not mean that it is admitted to be prior art.

### SUMMARY

The systems, methods and devices of this disclosure each have several innovative aspects, no single one of which is solely responsible for the desirable attributes disclosed herein. Included among these aspects are at least the following implementations, although further implementations may be set forth in the detailed description or may be evident from the discussion provided herein.

In some embodiments, a multi-station processing apparatus may be provided. The apparatus may include a processing chamber, a plurality of process stations in the processing chamber that each include a showerhead having a gas inlet and a faceplate, and a gas delivery system including a junction point and a plurality of flowpaths. Each flowpath may include a flow element, include a temperature control unit that is thermally connected with the flow element and that is controllable to change the temperature of that flow element, and fluidically connect one corresponding gas inlet of a process station to the junction point such that each process station of the plurality of process stations is fluidically connected to the junction point by a different flowpath.

In some embodiments, the temperature control unit may be controllable to change, via a temperature change, the flow conductance of the flow element with which it is in thermal contact.

In some embodiments, the temperature control unit may include a heating element configured to heat the flow element with which it is in thermal contact.

In some such embodiments, the heating element may include a resistive heating element, a thermoelectric heater, and/or a fluid conduit configured to flow a heating fluid within the fluid conduits.

In some embodiments, each showerhead may further include a temperature control unit that is thermally connected with the showerhead and that is controllable to change the temperature of a portion of the showerhead, and each flowpath may further fluidically connect the showerhead faceplate to the junction point.

In some such embodiments, the temperature control unit may be thermally connected with a stem of the showerhead and controllable to change the temperature of the stem.

In some such embodiments, the temperature control unit may be thermally connected with the faceplate and controllable to change the temperature of the faceplate.

In some such embodiments, the showerhead may further include a back plate, and the temperature control unit may be thermally connected with the back plate and controllable to change the temperature of the back plate.

In some such embodiments, the showerhead may be a flush-mount showerhead.

In some embodiments, the temperature control unit may be positioned at least partially inside the flow element on which it is positioned.

In some embodiments, the flow element of each flowpath may include a valve, and the temperature control unit of each flowpath may be controllable to heat the valve to change the flow conductance of the valve.

In some embodiments, the flow element of each flowpath may include a monoblock, and the temperature control unit of each flowpath may be controllable to heat the monoblock to change the flow conductance of the monoblock.

In some embodiments, the flow element of each flowpath may include a gas line, and the temperature control unit of each flowpath may be controllable to heat the gas line to change the flow conductance of the gas line.

In some such embodiments, the junction point is a mixing bowl.

In some embodiments, the flow element of each flowpath may include a fitting, and the temperature control unit of each flowpath is controllable to heat the fitting to change the flow conductance of the fitting.

In some such embodiments, the fitting may be a tee fitting.

In some embodiments, each flowpath may further include two temperature control units, and each temperature control unit in each flowpath may be in thermal contact with a different flow element of that flowpath.

In some embodiments, the apparatus may further include a controller configured to control the multi-station deposition apparatus to deposit a material onto substrates at the plurality of process stations. For a first flowpath fluidically connected to a first station of the plurality of process stations, a first temperature control unit may be in thermal contact with a first flow element, for a second flowpath fluidically connected to a second station of the plurality of process stations, a second temperature control unit may be in thermal contact with a second flow element, and the controller may include control logic for providing a substrate at each of the process stations, simultaneously depositing a first layer of material onto a first substrate at the first process station and a second layer of material onto a second substrate at the second process station, and maintaining, during at least a portion of the depositing, the first flow element at a first temperature and the second flow element at a second temperature different than the first temperature.

In some such embodiments, the maintaining the first flow element at the first temperature may include causing the first temperature control unit to heat the first flow element to the first temperature, and the maintaining the second flow element at the second temperature may include not causing the second temperature control unit to heat the second flow element.

In some such embodiments, the maintaining the first flow element at the first temperature may include causing the first temperature control unit to heat the first flow element to the first temperature, and the maintaining the second flow element at the second temperature may include causing the second temperature control unit to heat the second flow element to the second temperature.

In some such embodiments, the controller may further include control logic for maintaining, during at least a second portion of the depositing, the first flow element at a third temperature different than the first temperature, and the second flow element at a fourth temperature different than the second temperature.

In some such embodiments, during the maintaining the first flow element at a first temperature, the first flowpath may have a first flow conductance, and during the maintaining the second flow element at a second temperature, the second flowpath may have a second flow conductance different than the first flow conductance.

In some such embodiments, during the maintaining the first flow element at a first temperature, the first flowpath may have a first flow conductance, and during the maintaining the second flow element at a second temperature, the second flowpath may have a second flow conductance substantially equal to the first flow conductance.

In some such embodiments, the first layer of material deposited on the first substrate may have a first value of a property, and the second layer of material deposited on the second substrate may have a second value of the property substantially the same as the first value.

In some further such embodiments, the property may be a wet etch rate, a dry etch rate, a composition, a thickness, a density, an amount of cross-linking, a reaction completion, a stress, a refractive index, a dielectric constant, a hardness, an etch selectivity, a stability, of a hermeticity.

In some such embodiments, the first layer of material deposited on the first substrate may have a first value of a property, and the second layer of material deposited on the first substrate may have a second value of the property different than the first value.

In some such embodiments, the depositing may further include a temperature soak of the substrates, indexing, flowing a precursor, flowing a purge gas, flowing a reactant gas, generating a plasma, and/or activating the precursor on the substrates to thereby deposit the material onto the substrates.

In some embodiments, a method of depositing material onto substrates in a multi-station deposition apparatus having a first station with a first showerhead and a second station with a second showerhead may be provided. The method may include providing a first substrate onto a first pedestal of the first station, providing a second substrate onto a second pedestal of the second station, simultaneously depositing a first layer of material onto the first substrate and a second layer of material onto the second substrate, and maintaining, during at least a portion of the simultaneous depositing a first flow element of a first flowpath at a first temperature, in which the first flowpath fluidically connects a junction point to the first showerhead, and a second flow element of a second flowpath at a second temperature different than the first temperature, in which the second flowpath fluidically connects a junction point to the second showerhead.

In some embodiments, the maintaining the first flow element at the first temperature may include maintaining the first flowpath at a first flow conductance, and the maintaining the second flow element at the second temperature may include maintaining the second flowpath at a second flow conductance different than the first flow conductance.

In some embodiments, the maintaining the first flow element at the first temperature may include maintaining the first flowpath at a first flow conductance, and the maintaining the second flow element at the second temperature may include maintaining the second flowpath at a second flow conductance substantially the same as the first flow conductance.

In some embodiments, the maintaining the first flow element at the first temperature may include heating the first element, and the maintaining the second flow element at the second temperature may include not heating the second element.

In some embodiments, the maintaining the first flow element at the first temperature may include heating the first element, and the maintaining the second flow element at the second temperature may include heating the second element.

In some embodiments, the method may further include providing, before providing the first substrate and the second substrate, a third substrate onto the first pedestal, providing, before providing the first substrate and the second substrate, a fourth substrate onto the second pedestal, and simultaneously depositing a third layer of material onto the first substrate and a fourth layer of material onto the second substrate while not maintaining the first flow element at the first temperature and not maintaining the second flow element at the second temperature. A first nonuniformity between a property of the first layer of material on the first substrate and the property of the second layer of material on the second substrate, may be smaller than a second nonuniformity between the property of the third layer of material on the third substrate and the property of the fourth layer of material on the fourth substrate.

### BRIEF DESCRIPTION OF THE DRAWINGS

The various implementations disclosed herein are illustrated by way of example, and not by way of limitation, in the figures of the accompanying drawings, in which like reference numerals refer to similar elements.

FIG. 1 depicts a first example multi-station semiconductor processing tool.

FIG. 2 depicts a second example multi-station processing tool.

FIG. 3 depicts a first example technique for performing film deposition in a multi-station semiconductor processing chamber.

FIG. 4 depicts the fourth technique for performing film deposition in a multi-station semiconductor processing chamber.

FIG. 5 depicts a fifth example technique for performing film deposition in a multi-station semiconductor processing chamber.

FIG. 6 depicts a sixth example technique for performing film deposition in a multi-station semiconductor processing chamber.

FIG. 7 depicts a flowchart of an example sequence of operations for forming a film of material on a substrate via an ALD process.

FIG. 8 depicts a plot of material thickness for two substrates.

FIG. 9 depicts a plot of refractive index (RI) for two substrates.

FIG. 10 depicts a single-station substrate processing apparatus for depositing films on semiconductor substrates using any number of processes.

FIG. 11 depicts an example multi-station substrate processing apparatus.

FIG. 12A depicts an isometric view of an example showerhead according to disclosed embodiments.

FIG. 12B depicts a cross-sectional isometric view of the example showerhead of FIG. 12A.

FIG. 13 depicts a cross-sectional side view of an example flush-mount showerhead.

FIG. 14 depicts a third example multi-station semiconductor processing tool.

FIG. 15 depicts an isometric view of an example thermally controlled showerhead.

FIG. 16 depicts an isometric cutaway view of the example thermally controlled showerhead of FIG. 15.

FIG. 17 depicts an isometric partial exploded view of a portion of the thermally controlled showerhead of FIG. 15.

FIG. 18 depicts another isometric partial exploded view of the portion of the thermally controlled showerhead of FIG. 17.

FIG. 19 shows an isometric section view of a gas distribution manifold, in accordance with some implementations.

FIG. 20 shows an exploded view of the example gas distribution manifold of FIG. 19, in accordance with some implementations.

FIG. 21 shows a top view of an example of a heating plate assembly of the example gas distribution manifold of FIG. 19, in accordance with some implementations.

FIG. 22 shows a top view of an example of a cooling plate assembly of the example gas distribution manifold of FIG. 19, in accordance with some implementations.

### DETAILED DESCRIPTION

Semiconductor processing tools having multi-station processing chambers typically deliver process gases to each station by flowing the process gases from a common source to a junction point, and then through individual, typically nominally identical, flowpaths to a gas dispersion device at each station. The flow conductance between identically built flowpaths has been found to differ due to inherent variabilities, such as variabilities within manufacturing tolerances. Further, the flow conductances within these flowpaths have been found to affect properties of the material deposited on substrates, such as material thickness and refractive index. While such variabilities are often sufficiently small that they did not affect process conditions for performing semiconductor device fabrication operations in earlier technology nodes or in single station reactors. However, design constraints and advanced fabrication technologies leave little room for even what have formerly been considered a miniscule variance in flow conductance.

It has been discovered that the flow conductance of an element in a flowpath may be adjusted by, among other things, adjusting the temperature of that element. Accordingly, described herein are techniques and apparatuses for adjusting one or more flow conductance of elements within a flowpath to modify or tune a flow characteristic of the flowpath. This in turn may serve to adjust deposited material properties, and/or improve station-to-station matching of deposited material properties. To improve station-to-station matching, the conductances of flow elements in lines to different stations of a single multi-station chamber may be adjusted independently of one another by, for example, independently controlling the temperatures of the flow elements in the different lines to the different stations.

As mentioned, the flow conductance of two nominally identical flow elements in different flowpaths may differ because of variability within a manufacturing tolerance. By adjusting the temperature of one of these elements the flow conductance of that element is correspondingly adjusted so that the flow conductance of the two flow elements matches. In another example, a property of deposited material at two different stations within the same processing chamber may differ. For one of the stations, the temperature of one flow element in the flowpath for that station may be adjusted in order to adjust the flow conductance of that flowpath, adjust the property of deposited material at that station, and more closely match the property at the other station. In another example, the flow rate or other flow property through an inlet line to a process chamber may deviate slightly from specification. To adjust the flow property to fall within the specification, the temperature of an element along the inlet line may be adjusted in planned manner.

Some semiconductor processes are used to deposit one or more layers of a material onto a substrate using various techniques, such as chemical vapor deposition (“CVD”), plasma-enhanced CVD (“PECVD”), atomic layer deposition (“ALD”), low pressure CVD, ultra-high CVD, and physical vapor deposition (“PVD”). CVD processes deposit a film on a wafer surface by flowing one or more gas reactants (also called precursors) into a reactor where they react, optionally with the assistance of a plasma as in PECVD, to form a product (typically the film) on a substrate surface. In ALD processes, precursors are transported to the wafer surface where they are adsorbed by the wafer and then converted by a chemical or physicochemical reaction to form a thin film on the substrate. A plasma may be present in the chamber to facilitate the reaction. ALD processes employ multiple film deposition cycles, each producing a “discrete” film thickness.

ALD produces relatively conformal films because a single cycle of ALD deposits only a single thin layer of material, the thickness being limited by the amount of one or more film precursor reactants which may adsorb onto the substrate surface (i.e., forming an adsorption-limited layer) prior to the film-forming chemical reaction itself. Multiple “ALD cycles” may then be used to build up a film of the desired thickness, and since each layer is thin and conformal, the resulting film substantially conforms to the shape of the underlying devices structure. In certain embodiments, each ALD cycle includes the following steps:
1. Exposure of the substrate surface to a first precursor.
2. Purge of the reaction chamber in which the substrate is located.
3. Activation of a reaction of the substrate surface, optionally by exposure to high temperature and/or a plasma, and/or by exposure to a second precursor.
4. Purge of the reaction chamber in which the substrate is located.

The duration of each ALD cycle may be less than 25 seconds or less than 10 seconds or less than 5 seconds. The plasma exposure step (or steps) of the ALD cycle may be of a short duration, such as a duration of 1 second or less, for example. The precursor exposure step may be of similarly short duration. During such short durations, precise control of flow properties of gases introduced to the process chamber is very important. This challenge is compounded by the continuing reduction in the size of semiconductor device feature sizes and the use of increasing complicated feature geometries such in 3D devices structures. In such applications, a film deposition process must produce films of precisely controlled thickness, often with high conformality (films of material having a uniform thickness relative to the shape of the underlying structure, even if non-planar).

For the purposes of this disclosure, the term “fluidically connected” is used with respect to volumes, plenums, holes, etc., that may be connected with one another in order to form a fluidic connection, similar to how the term “electrically connected” is used with respect to components that are connected together to form an electric connection. The term “fluidically interposed,” if used, may be used to refer to a component, volume, plenum, or hole that is fluidically connected with at least two other components, volumes, plenums, or holes such that fluid flowing from one of those other components, volumes, plenums, or holes to the other or another of those components, volumes, plenums, or holes would first flow through the “fluidically interposed” component before reaching that other or another of those components, volumes, plenums, or holes. For example, if a pump is fluidically interposed between a reservoir and an outlet, fluid that flowed from the reservoir to the outlet would first flow through the pump before reaching the outlet.

### I. Introduction to Flow Conductance

As fluid travels through a flowpath from one plenum to another plenum, that flowpath presents a restriction that resists fluid flow. The relative ease with which a fluid flows is considered the conductance, or flow conductance, which is generally represented by the following equation:

$$C = \frac{Q}{{P}_{u} - {P}_{d}} ,$$

where C is the conductance, Q is the flowrate, Pᵤ is the pressure upstream of the flowpath, and P_{d} is the pressure downstream of the flowpath. Flow conductance may be analogous to electrical conductance, with the flowrate analogous to current and the pressure differential analogous to the voltage differential. The inverse of flow conductance, like electrical conductance, is resistance, flow resistance or electrical resistance as the case may be. Thus, the flow path itself is said to have a flow conductance and flow resistance. For flowpaths with multiple, serially connected, elements and pressure differentials, the net conductance of that flowpath is the inverse of the sum of the inverses of the individual conductances; similarly, the net resistance is the sum of the resistances.

Multi-station processing tools typically have a single processing chamber that includes multiple stations, such as 2, 4, 6, or 8 stations, where substrates may be simultaneously processed. Each station generally includes a substrate support structure, such as a pedestal or electrostatic chuck, and a showerhead for delivering process gases to the substrate at that station. Multi-station processing tools also typically include a gas delivery system with gas (or liquid) sources, valves, gas lines, and other flow elements configured to transport process gases to the showerheads of each station, with each showerhead configured to distribute process gases in a relatively even manner across a substrate in the station. Part of the gas delivery system includes a plurality of flowpaths, with each flowpath fluidically connecting one corresponding showerhead to a common junction point. It is typically desirable to create the same, uniform flow conditions in all of the stations so that the parallel processing at these stations creates uniform processing results between stations. Because of this, the flowpaths are typically constructed to be as identically as possible so that the gas flow between the junction point, such as a mixing chamber, and the showerhead are as similar as possible. For instance, more gas tends to flow through higher conductance flowpaths which can result in mismatched flow at the corresponding processing stations if the flowpath flow conductances are mismatched.

In some instances, each flowpath may be considered to include the showerhead itself; each flowpath may therefore extend between the common junction point and the fluidic connection of the showerhead to the processing station. The showerheads in the stations may also be constructed similarly to each other to create uniform flow conditions in and between stations.

Despite the use of the same components and design, many flowpaths have different conductances due to numerous reasons, such as inherent variabilities of flow elements within the flowpaths, even quite small variabilities, and these differences can adversely affect processing characteristics and wafer uniformity. For example, a valve used in a flowpath may have a variable flow conductance due to manufacturing tolerances, such as +/−3%. This variability prevents, in some applications, a sufficiently tight control of flow conductance through that flowpath and may also cause a different flow in that flowpath as compared to other flowpaths. Flow conductance variability of a flowpath, and between flowpaths, is compounded when additional flow elements, each with its own variable flow conductance, are included in a flowpath. As an example, a single flowpath may contain multiple, serially-arranged, valves. It is therefore advantageous to have the ability to adjust flow conductance of one or more flow elements in a flowpath in order to, among other things, account for flow conductance variability of the individual elements and overall flowpath.

Additionally, deviation from a precisely specified flow property (e.g., flow rate) due to deviation of the flow conductance of a flowpath from a precisely specified flow conductance may affect one or more properties of the material deposited on the substrate, such as a material's thickness and/or refractive index (“RI”). For example, as discussed in more detail below, increasing the flow conductance for a flowpath may decrease the resulting material thickness and may increase the resulting RI. Of course, other deposited film properties may also be affected. Examples include composition, crystallinity, internal stress, extinction coefficient, dielectric constant, density, dielectric breakdown voltage, and the like. Adjusting the flow conductance of one or more flow elements in a flowpath may allow fine tuning of any one or more of these properties. And, by permitting independent adjustment of flow conductances in different input lines feeding different stations of multi-station chamber, the methods and apparatus may be implemented to reduce station-to-station nonuniformity.

### II. Flow Conductance Adjustments

In accordance with certain embodiments, flow conductance through a flow element is adjusted by changing the temperature of that flow element. In some instances, the flow conductance decreases, and flow resistance increases, as temperature increases because, as a first approximation according to the ideal gas law, pressure increases as temperature increases and because gas viscosity tends to increase as temperature increases. Separately, flow conductance may increase or decrease with an increased temperature due to a changed geometry of the flow element caused by thermal expansion. For example, a heated tube may expand and get bigger which may increase flow conductance through that tube. In another example, a heated polymeric valve seat of a valve may also expand which could restrict the flow conductance through that valve.

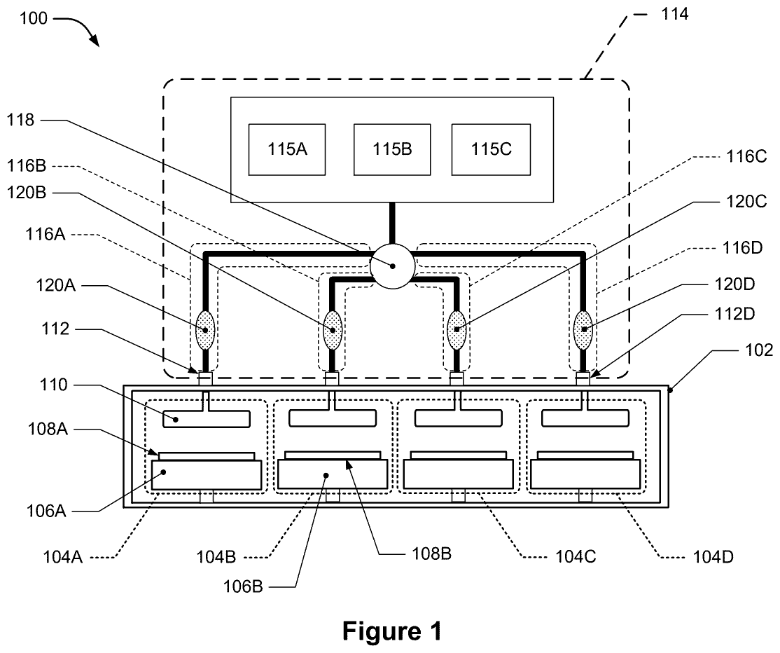

Accordingly, the apparatuses and techniques described herein adjust the temperature of flow elements of the flowpaths in order to adjust the flow conductance through these flow elements, adjust the properties of deposited materials, and reduce station-to-station variations. FIG. 1 depicts a first example multi-station semiconductor processing tool (hereinafter “tool”). This tool 100 includes a processing chamber 102 with four processing stations 104A-104D, each is encompassed by a dotted box; each station includes a pedestal 106 with a substrate 108A on the pedestal 106A, and a showerhead 110 with a gas inlet 112; these items are labeled in processing station 104A.

The tool 100 also includes a gas delivery system 114 fluidically coupled to each processing station 104A-104D for delivering process gases to the showerheads 110, which may include liquids and/or gases, such as film precursors, carrier and/or purge and/or process gases, secondary reactants, etc. The gas delivery system 114 may include other features, graphically represented as boxes 115A-115C, such as one or more gas sources, a mixing vessel, and a vaporization point for vaporizing liquid reactant to be supplied to mixing vessel, as well as valves and gas lines to direct and control the flow of gases and liquids throughout the gas delivery system 114. The showerhead distributes process gases and/or reactants (e.g., film precursors) toward the substrate at the processing station.

As also seen in FIG. 1, the gas delivery system 114 includes four flowpaths 116A-116B that are each fluidically connected to a junction point 118 and the gas inlet 112 of a corresponding processing station. For example, flowpath 116A is fluidically connected to, and spans between, the junction point 118 and the gas inlet 112 of processing station 104A such that gas flows from the junction point 118 to the gas inlet 112 through the flowpath 116A; each of these flowpaths extends from the junction point 118 to the gas inlet 112. These flowpaths are encompassed by dashed shapes, shown as illustrative representations, and are not an accurate, precise schematic of the gas delivery system. The junction point 118 may be considered a common point in the gas delivery system from which two or more of the individual flowpaths, or legs, branch out to the individual processing stations. In some embodiments, this may be considered the point where identical, or nearly identical, flowpaths to processing stations begin. In some embodiments, there may be multiple junction points, or sub-junction points, such that some flowpaths begin at a first junction point and other flowpaths begin at a second junction point. Referring to FIG. 1, flowpaths 116A and 116B may extend from a first junction point while flowpaths 116C and 116D may extend from a different, second junction point to their respective processing stations. As described below, in some embodiments, each flowpath may further include the corresponding showerhead such that each flowpath spans between the junction point 118 and one or more points on each showerhead in each station, such as the fluidic connection between the showerhead and the processing station's plenum volume.

In some embodiments, as depicted in FIG. 1, the gas inlet 112 may be considered outside the processing chamber 102. In these embodiments, the flowpath may be considered positioned outside the processing chamber. In some other embodiments, the gas inlet may be inside or partially inside the processing chamber 102 and in these embodiments the flowpaths may extend inside or partially inside the processing chamber 102.

Each of the flowpaths also includes a temperature control unit that is configured and controllable to change the temperature of a flow element within that flowpath. As seen in FIG. 1, the flowpaths 116A-116D each have a single temperature control unit 120A-120D, respectively. In some embodiments, the temperature control unit may be configured to heat the flow element and may include a heating element, such as a resistive heater, thermoelectric heaters, or fluid conduits to flow a heating fluid. In some embodiments, the temperature control unit may also be configured to cool the flow element, such as by having fluid conduits through which a cooling fluid may flow. The temperature control unit may be positioned on, around, or within the flow element. For example, the temperature control unit may be a heater jacket and it may be positioned on the flow element by being wrapped around a pipe or valve; in another example, the temperature control unit may be a resistive heating element that is positioned within the flow element by being embedded within a pipe, or a valve or block through which the fluid flows.

As stated, in some embodiments the temperature control unit may be positioned within, or at least partially inside, the flow element on which it operates. In some embodiments, at least one part of the temperature control unit is embedded within a part of the flow element. For instance, a resistive heating element or heating fluid conduits may be embedded inside the wall of a pipe or inside a body of a valve. In some instances, the embedded part of the temperature control unit is positioned so that it does not contact the fluid. For example, the resistive heating element embedded into the pipe wall may not extend through the inner pipe wall and into the pipe interior where gas flows. The fluid conduits may be pathways, such as channels or tubes, through which a fluid can flow, and the fluid is heated to an elevated temperature, e.g., a temperature above ambient temperature which may be at least as high as the desired temperature of the fluid conduit, such as at least 80 C, 100, C, or 110 C, for instance. The heating fluid may be a heated gas (e.g., an inert gas like argon or nitrogen) or a heated liquid (e.g., water, a glycol/water mixture, a hydrocarbon oil, or a refrigerant/phase change fluid).

By adjusting the temperature of the flow element, such as by heating, the temperature control unit is further configured and controllable to adjust the flow conductance of that flow element. As stated above, changing the temperature for some flow elements, such as a pipe or valve, can change the flow conductance through that flow element. Using temperature to control flow conductance is advantageous because, generally speaking, flow conductance of flow elements cannot be changed once the element is manufactured or installed. For instance, the flow conductance of valves are typically fixed once they are manufactured and therefore cannot be adjusted “on the fly.” For example, as stated above, most valves have manufacturing tolerances, such as +/−3% which generally cannot be changed, absent physical modification of the valve. However, adjusting the temperature of a valve as described herein can adjust the flow conductance of the valve in order to reduce its variability, such as reducing it to less than or equal to +/−2%, +/−1%, or +/−0.5%.

Although tool 100 is shown with four stations, other embodiments of the tools may have more or less stations, such as 2, 6, 8, or 10 stations, for example. These tools may be configured the same, such that each processing station has a corresponding flowpath that extends between that station and a junction point, and that includes at least one temperature control unit. In some embodiments, each flowpath may have more than one temperature control unit and each flowpath may have multiple and different flow elements.

For example, in some embodiments like depicted in FIG. 1, the tool 100 may have a single junction point 118 that may be considered a mixing bowl where processing gas is flowed and mixed. Connected to the mixing bowl 118 may be four identical (or intended to be identical except for, for instance, minor construction and manufacturing differences) flowpaths 116A-116D, even though in FIG. 1 these are not illustrated as identical, that each extend to a gas inlet at a corresponding processing station, as described above. For example, flowpath 116A extends from the mixing bowl 118 to the gas inlet 112 of processing station 114A; similarly, flowpath 116D extends from the mixing bowl 118 to the gas inlet 112D of processing station 114D. In some such embodiments, these flowpaths may include tubing elements and no valves. Each temperature control element may be a heater positioned around a portion of the tube for that flowpath. This portion may be considered a circumferential portion along part or all of the outer circumference of the tube and a longitudinal portion along part or all of the length of the tube.

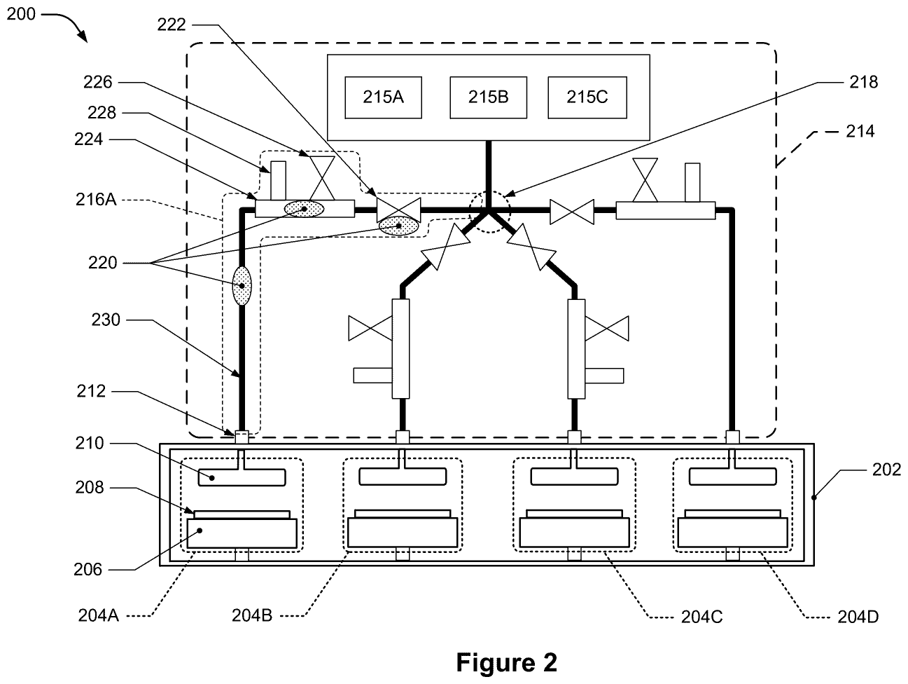

In some other embodiments, the tool may have flowpaths that include multiple, different flow elements which may be temperature controlled. FIG. 2 depicts a second example multi-station processing tool. Here, tool 200 includes the same four processing stations 204A-204D as in FIG. 1, but the four flowpaths of the gas delivery system 214 are different. Each flowpath 216A-216D, only one of which is identified within a dashed shape, extends between the junction point 218 and the gas inlet 212 of a corresponding processing station. Each flowpath also includes multiple flow elements, such as those identified for flowpath 216A including a valve 222, a monoblock 224 to which other flow components are attached, such as a second valve 226 and a mass flow controller 228, and one or more gas lines 230. Although not identified, the other three flowpaths 216B-216D include these same flow elements. As further illustrated, the temperature control unit 220 may be positioned on or within one or more of these flow elements. For example, as seen in FIG. 2, temperature control units 220 are positioned on the valve 222, within the monoblock 224, and on the gas line 230. The temperature control unit may adjust the flow conductance of each of these elements by adjusting the temperature of that flow element. Although not shown in FIG. 1 or 2, in some embodiments, each flowpath may include other flow elements that may be temperature controlled, such as a fitting, including a tee fitting, at a junction point (other than the junction point 118) within the flowpath; this may include a fitting at a junction between two or three lines within the flowpath. As with the other flow elements, a temperature control unit may be positioned on or within these other flow elements which may be configured to adjust the flow conductance of each of these elements by adjusting the temperature of that flow element.

As mentioned above, each flowpath may further include the corresponding showerhead, and the flow conductance of each showerhead may be adjustable by controlling the temperature of one or more aspects of the showerhead. The showerheads described herein may include a plenum volume that is bounded by a back plate and a faceplate that fronts a semiconductor processing volume in which semiconductor substrates may be processed. The faceplate may include a plurality of gas distribution holes that allow gas in the plenum volume to flow through the faceplate and into a reaction space between the substrate and the faceplate (or between a wafer support supporting the wafer and the faceplate). Similar to other flow elements through which gas flows, some features of a showerhead, such as the configuration of the internal surfaces and features of the back plate and/or the faceplate, and the configuration of the through-holes (e.g., their diameter and spacing from each other), may affect and restrict the gas flow through the showerhead. Controlling the temperature of one or more aspects of the showerhead can adjust the flow conductance through the showerhead in order to, for instance, cause a more uniform flow through the showerhead and/or reduce wafer non-uniformity.

Showerheads are typically classified into broad categories: flush-mount and chandelier-type. Flush-mount showerheads are typically integrated into the lid of a processing chamber, i.e., the showerhead serves as both a showerhead and as the chamber lid. Chandelier-type showerheads do not serve as the lid to the processing chamber, and are instead suspended within their semiconductor processing chambers by stems that serve to connect such showerheads with the lids of such chambers and to provide a fluid flow path or paths for processing gases to be delivered to such showerheads. The showerheads in FIGS. 1, 2, 12, and 14 are illustrated as chandelier-type showerheads. In some embodiments, any of the showerheads described herein may be flush-mount showerheads.

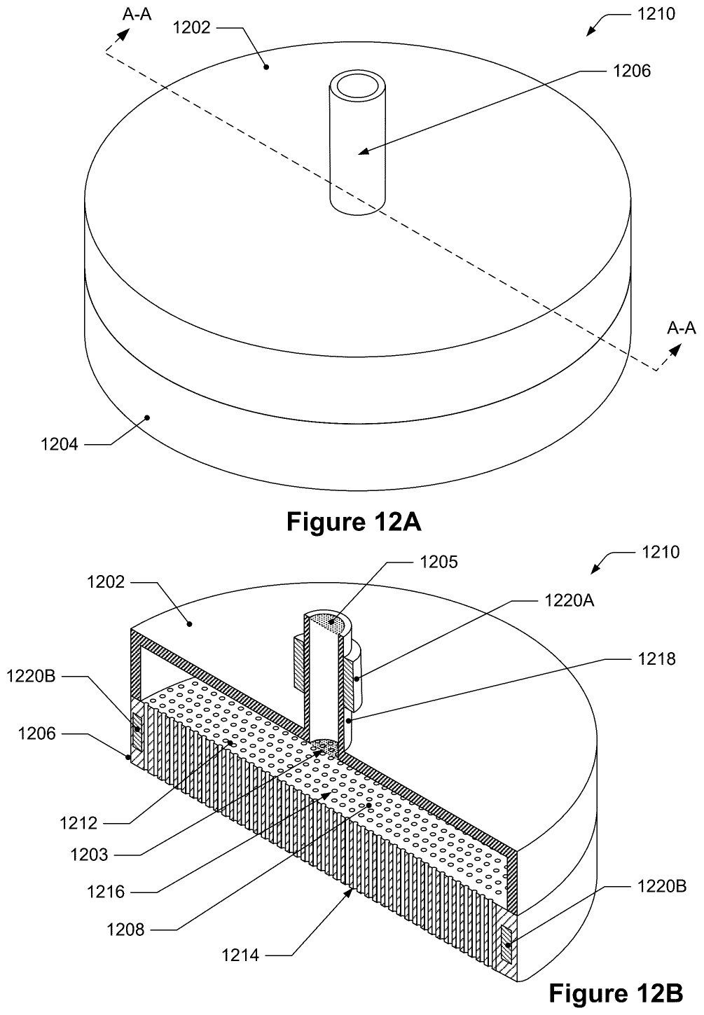

FIG. 12A depicts an isometric view of an example showerhead according to disclosed embodiments, and FIG. 12B depicts a cross-sectional isometric view of the showerhead of FIG. 12A. The cross-sectional view of FIG. 12B is taken along section line A-A in FIG. 12A. Showerhead 1210 is an illustrative chandelier-type showerhead having a stem 1218. In these Figures, the showerhead 1210 includes a back plate 1202 with a plenum inlet 1203, and a faceplate 1204 connected to the back plate 1202. The gas inlet 1205 of the showerhead 1210 may be considered the point where gas flows into the stem of the showerhead 1210; this gas inlet 1205 may be considered the gas inlet described herein, such as the gas inlet 112 and 212 of FIGS. 1, 2, and 13. The back plate 1202 and faceplate 1204 together partially define a plenum volume 1208 within the showerhead 1210, and in some instances, a baffle plate (not shown) may be positioned within the plenum volume 1208. The back plate 1202 and the faceplate 1204 may be positioned opposite one another within the showerhead such that they have surfaces that face each other. The faceplate 1204 includes a back surface 1212 that partially defines the plenum volume 1208 and faces the back plate 1202, and a front surface 1214 that is configured to face a substrate positioned within the processing chamber. The faceplate 1204 also includes a plurality of through-holes 1216 (one is identified in FIG. 12B) that extend through the faceplate 1204 from the back surface 1212 to the front surface 1214 and allow fluid to travel from the plenum volume 1208 to outside of the showerhead 1210 and onto a substrate.

Some showerheads may include one or more temperature control units to control the temperature of one or more aspects and thus adjust the flow conductance of the showerhead. The showerhead of FIGS. 12A and 12B includes temperature control units that may be used to control a showerhead's temperature. In some embodiments, the showerhead 1210 may include one or more temperature control units configured to control the temperature of the showerhead stem 1218. In some instances, controlling the temperature, and thus flow conductance, of the stem upstream from the showerhead's restrictive flow elements, such as the plenum volume 1208 and the plurality the through-holes 1216, enables more accurate and uniform flow conductance control and adjustment through the showerhead. As representationally illustrated in FIGS. 12A and 12B, showerhead 1210 includes one temperature control unit 1220A positioned on the stem 1218 in order to heat, control the temperature of, and thus control the flow conductance of the stem 1218. The temperature control unit 1220A may be a single unit or a plurality of units. The temperature control unit 1220A may include one or more resistive heaters positioned around and/or within the stem 1218, one or more fluid conduits positioned around or within the stem 1218 and configured to flow heat transfer fluid, such as heated water, in order to heat the stem, or one or more cartridge heaters positioned in holes in the stem 1218.

In some embodiments, the temperature control unit 1220A may also include one or more cooling elements configured to actively cool the stem 1218, such as one or more fluid conduits positioned around or within the stem 1218 and configured to flow heat transfer fluid, such as cooled water, and cool the stem 1218. In some such embodiments, the temperature control unit 1220A may have two parts, with a first part as the heating part configured to heat the stem 1218 and the second part as the cooling part configured to cool the stem 1218. Each of these parts may include a sub-set of portions, such as the first part including multiple heating elements.

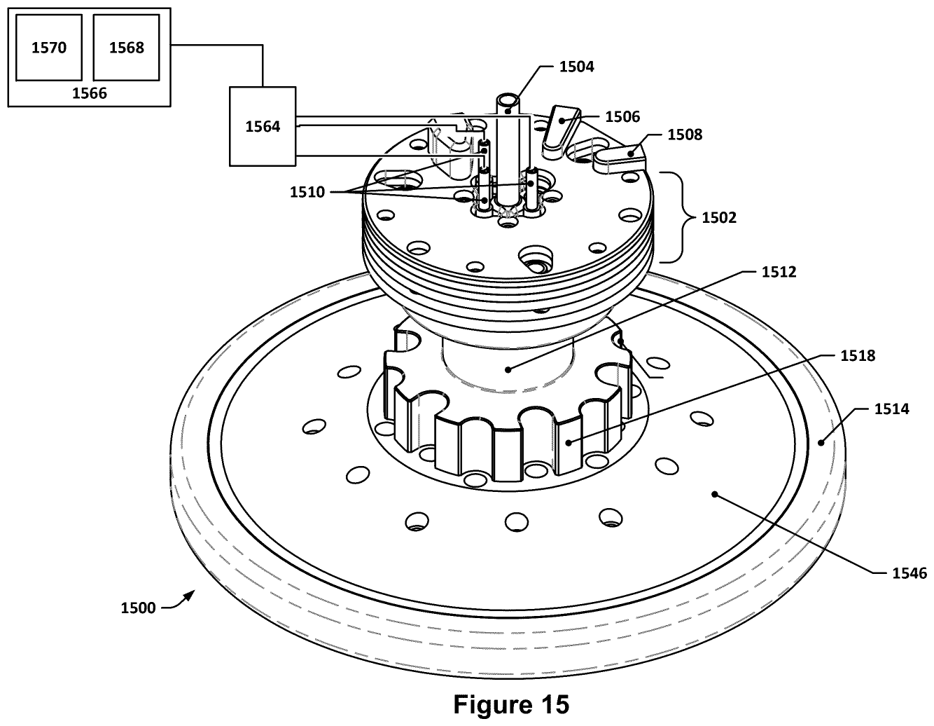

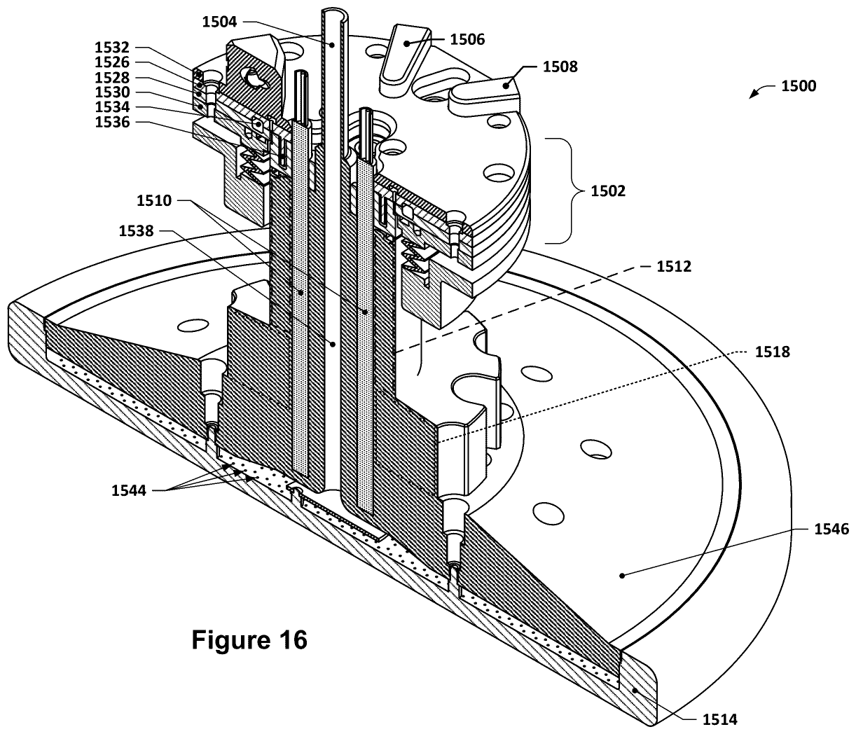

FIG. 15 depicts an isometric view of an example thermally controlled showerhead; FIG. 16 depicts an isometric cutaway view of the example thermally controlled showerhead of FIG. 15. In FIGS. 15 and 16, a showerhead 1500 is shown. The showerhead 1500 includes a faceplate 1514, which may have a large number of gas distribution holes 1544 in the underside (not visible in FIG. 15 but see FIG. 16). The faceplate 1514 may be connected with a backplate 1546, which may, in turn, be structurally and thermally connected with a cooling plate assembly 1502 by a stem 1512 and, in some implementations, a stem base 1518. The stem 1512 may include one or more holes, e.g., gun-drilled holes, that may be sized so as to receive, for example, a cartridge heater or a heater element 1510. In the depicted example showerhead 1500, there are three heater elements 1510 that are positioned along three sides of a gas inlet 1504 of the stem 1512 and that extend along nearly the entire length of a central gas passage 1538 (see FIG. 16). In some implementations, an additional hole or bore may be provided that extends to a similar depth and may be configured to receive a temperature probe, e.g., a thermocouple, that may be inserted therein to measure temperatures in the showerhead 1500 close to the gas distribution plenum.

The cooling plate assembly 1502 may, as shown, have a layered construction, although other implementations may provide a similar structure using other manufacturing techniques, e.g., additive manufacturing or casting. The cooling plate assembly 1502 may include a cover plate 1532 that is bonded, e.g., via diffusion bonding or brazing, to a first plate 1526, which is, in turn, bonded to a second plate 1528, which is, in turn, bonded to a third plate 1530. It will be understood that while such structures are referred to as “plates” in this application, they may include features that extend away from an otherwise generally planar surface, leaving the “plates” as having 3-dimensional structures that give such structures non-planar appearances.

The cooling plate assembly 1502 may include an inner cooling channel 1536 that extends generally around the stem 1512 and which may be fluidically connected within the cooling plate assembly 1502 so as to cause coolant flowed therethrough from a coolant inlet 1506 to subsequently flow through an outer cooling channel 1534, which may encircle (or at least partially encircle) the inner cooling channel 1536, before flowing to a coolant outlet 1508.

When the showerhead 1500 is installed in a semiconductor processing system, it may be connected to several additional systems. For example, the heater elements 1510 may be connected with a heater power supply 1564 that may provide electrical power to the heater elements 1510 under the direction of a controller 1566. The controller 1566 may, for example, have one or more processors 1568 and one or more memory devices 1570. The one or more memory devices may, as discussed later herein, store computer-executable instructions for controlling the one or more processors to perform various functions or control various other pieces of hardware.

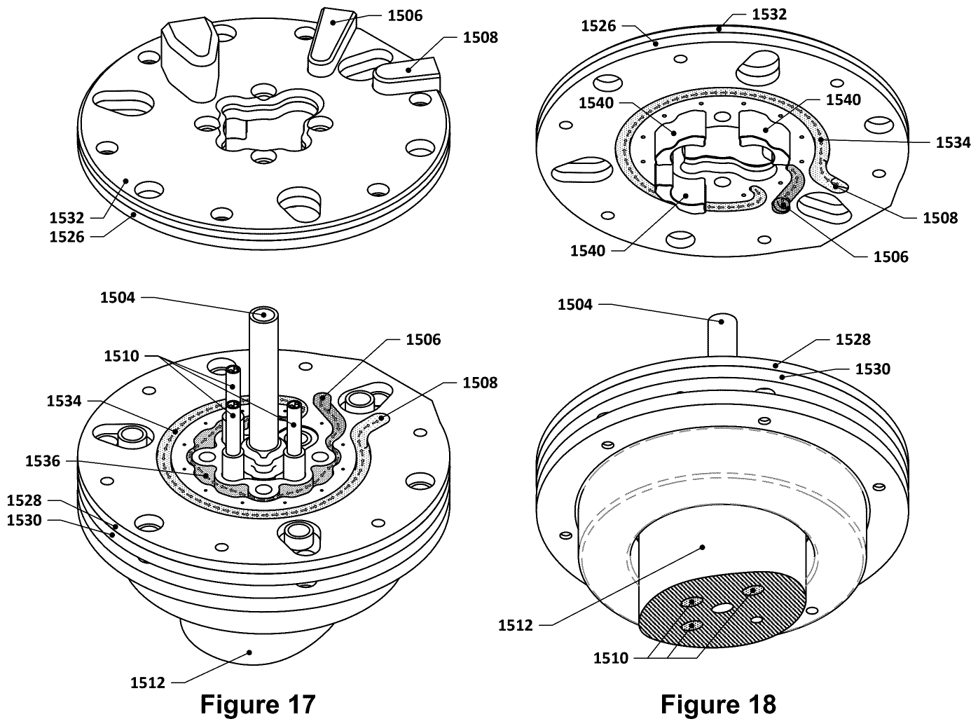

FIGS. 17 and 18 depict isometric partial exploded views of a portion of the thermally controlled showerhead of FIG. 15. In FIGS. 17 and 18, the cover plate 1532 and the first plate 1526 have both been removed, exposing the cooling flow paths within the cooling plate assembly 1502. As can be seen, the central gas passage 1538 may be located in close proximity to the heater cartridges 1510, which may be used to provide heat to the gases flowed within the central gas passage 1538. The inner cooling channel 1536 and the outer cooling channel 1534 are clearly visible. As can be seen, the outer cooling channel 1534 is formed by two matching channels in the first plate 1526 and the second plate 1528 that align when the various plates are assembled. The outer cooling channel 1534 may extend around all or nearly all, e.g., ˜300° of arc, of the central gas passage 1538. One end of the outer cooling channel 1534 may be fluidically connected with the inner cooling channel 1536, which may allow coolant that is flowed through the inner cooling channel 1536 to subsequently be flowed through the outer cooling channel 1534 without leaving the cooling plate assembly and then through the coolant outlet 1508.

As can be seen in FIG. 18, the first plate 1526 has a first surface that is bonded to a second surface of the second plate 1528 to form part of the cooling plate assembly. The first surface may optionally include one of the matching channels discussed above, as well as a plurality of protrusions 1540, each of which may be placed and sized so as to protrude into a correspondingly or similarly shaped portion of the inner cooling channel 1536, thereby forming a fluid flow passage having a very thin, U-shaped cross-section that generally causes the fluid that is flowed through the inner cooling channel 1536 to accelerate in the regions where the protrusions are, thereby increasing the Reynolds number of the cooling fluid in such regions and increasing heat transfer between the cooling fluid and the walls of the inner cooling channel 1536, and between the cooling fluid and the protrusions 1540; this increases the cooling efficiency of the inner cooling channel 1536.

The protrusions 1540 may be sized such that the gap between the bottom of the inner cooling channel 1536 and the facing surface of the protrusions 1540 is approximately the same as the gap between the side walls of the inner cooling channel 1536 and the facing surfaces or side walls of the protrusions 1540. For example, in the example showerhead 1500, the gap between the side walls of the inner cooling channel 1536 and the facing surfaces or side walls of the protrusions 1540 is approximately 1 mm, and the gap between the bottom of the inner cooling channel 1536 and the facing surface of the protrusions 1540 is approximately 1.3 mm. The protrusions 1540, in this example, extend approximately 14 mm from the first plate 1526; this results in the inner cooling channel having a volume of approximately 7.2 cubic cm. In comparison, the outer cooling channel, which has height of approximately 6 mm and width of approximately 6.3 mm, has a volume of approximately 9.6 cubic cm; an additional approximately 1.4 cubic cm and 0.8 cubic cm are contributed by the volumes of the inlet and outlet within the cooling plate assembly, respectively. In such an arrangement, a coolant flow of approximately 3800 to 5700 cubic cm per minute may be supplied to the cooling channels, resulting in approximately 200 to 300 complete replacements of the cooling fluid within the cooling channels of the cooling plate assembly 1502 per minute; cooling fluids such as water, fluorinated coolants (such as Galden® PFPE from Solvay), or other cooling liquids. This may allow the cooling plate assembly to be kept at a temperature of approximately 20° C. to 60° C. while the showerhead faceplate 1514 is kept at a temperature of approximately 300° C. to 360° C., e.g., 350° C. It will be understood that the particular dimensions and performance characteristics discussed above with respect to the example showerhead 1500 are not intended to be limiting, and that other showerheads with different dimensional and performance characteristics may fall within the scope of this disclosure as well.

It will be further noted that the protrusions 1540 extend downward from the first plate 1526, towards the faceplate 1514. Thus, heat from the faceplate 1514 and stem 1512 may flow along the sidewalls of the inner cooling channel 1536 and towards the first plate 1526, as well as from the first plate 1526 and to the ends of the protrusions 1540, i.e., in the opposite direction. This may have the effect of evening out the heating of the coolant flowing through the inner cooling channel, as the temperature gradient of the inner cooling channel 1536 side walls may be highest at the bottom of the inner cooling channel 1536, i.e., closest to the faceplate 1514, and lowest near the top of the inner cooling channel 1536, i.e., near the first plate 1526, whereas the temperature gradient in the protrusions 1540 may be reversed, i.e., with the highest temperature near the first plate 1526 and the lowest temperature near the bottom of the inner cooling channel 1536. This promotes more efficient heat transfer.

As further illustrated in FIG. 12B, the faceplate 1204 of the showerhead 1210 may additionally or alternatively include one or more temperature control units 1220B configured to heat, cool, or both, the faceplate 1204. These temperature control units 1220B may include one or more resistive heaters positioned within the faceplate 1204, in direct contact with the faceplate 1204, and/or thermally connected to the faceplate 1204. When a temperature control unit 1220B is thermally connected with the faceplate 1204, as also generally described herein, thermal energy is configured to travel directly between these items or indirectly through other thermally conductive material, such as a thermally conductive plate (e.g., that comprise a metal) that is interposed between the temperature control unit 1220B and the faceplate 1204. Alternatively, or in addition, the temperature control units 1220B may include one or more fluid conduits positioned within or in thermal contact with the faceplate 1204 and configured to flow heat transfer fluid, such as heated water and/or cooled water, and heat and/or the faceplate 1204.

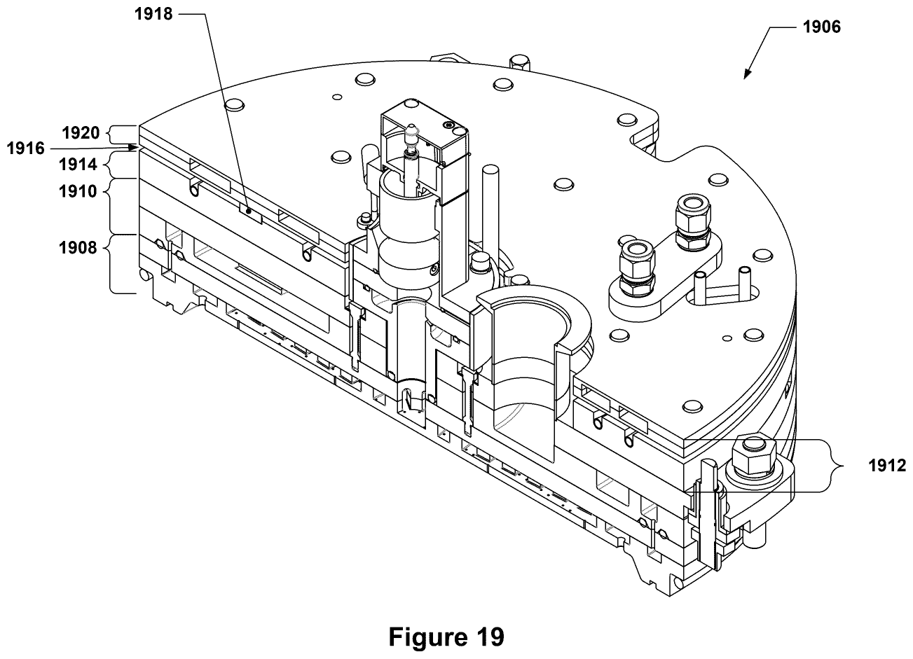

FIG. 19 shows an isometric section view of a gas distribution manifold 1906, such as a showerhead, in accordance with some implementations. The gas distribution manifold 1906 may contain a variety of components. For example, the gas distribution manifold 1906 may include a faceplate assembly 1908 that may be in thermally conductive contact with a temperature control assembly 1912; the temperature control assembly 1912 is in thermally conductive contact with a vacuum manifold 1910, which is in thermally conductive contact with the faceplate assembly 1908. The temperature control assembly 1912 may include a cooling plate assembly 1920, a heating plate assembly 1914 offset from the cooling plate assembly 1920 to form a gap 1916, and a plurality of thermal chokes 1918 distributed within the gap 1916, each of which are described in further detail below.

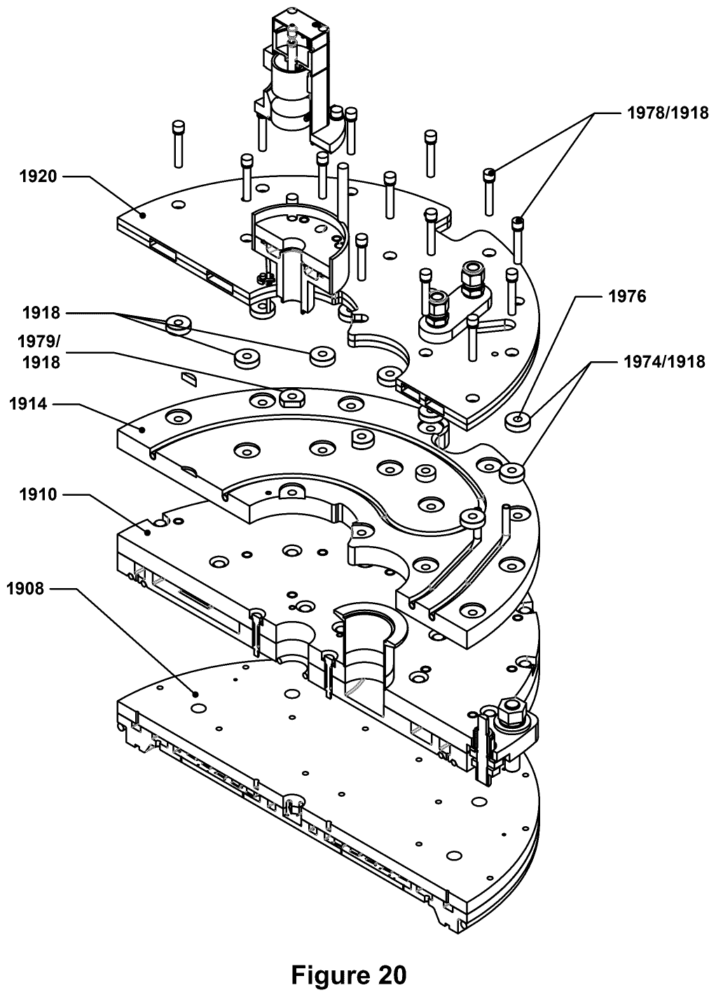

FIG. 20 shows an exploded isometric section view of the gas distribution manifold 1906 of FIG. 19, in accordance with some implementations. FIG. 20 separately illustrates some components and features of the gas distribution manifold 1906, such as the thermal chokes 1918, which can be seen in FIG. 20 between the cooling plate assembly 1920 and the heating plate assembly 1914.

The thermal chokes 1918 may provide a configurable thermally conductive pathway between the cooling plate assembly 1920 and the heating plate assembly 1914. In some implementations, the thermal chokes 1918 may be configured to dissipate a designated amount of heat required for semiconductor manufacturing operations performed by the gas distribution manifold 1906.

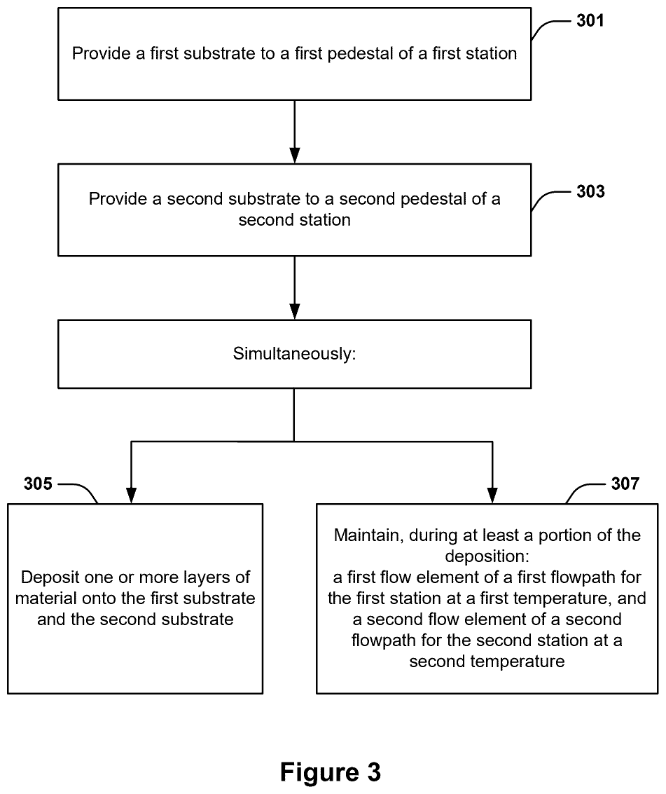

As shown in FIG. 20, each of the thermal chokes 1918 may include a spacer 1974. Each spacer may include a center region 1976, and each thermal choke 1918 may include a bolt 1978 that passes through the center region 1976. The thermal chokes 1918 may be composed of a variety of materials based on the amount of thermal conductivity that is desired. For example, in order of decreasing thermal conductivity, the thermal chokes 1918 may be composed of copper, aluminum, steel, or titanium. The thermal chokes 1918 may vary in size across implementations depending on how much heat dissipation is desired. However, thermal chokes 1918 may have a total cross-sectional area (including the spacer 1974 and the bolt 1978) in a plane parallel to the second exterior surface of FIG. 3 that is between 1.7% and 8.0% of the surface area of the first exterior surface 1926, e.g., 1.7% to 8% of the surface area of the faceplate assembly facing towards the thermal chokes and which is in conductive contact with the temperature control assembly or the vacuum manifold assembly.

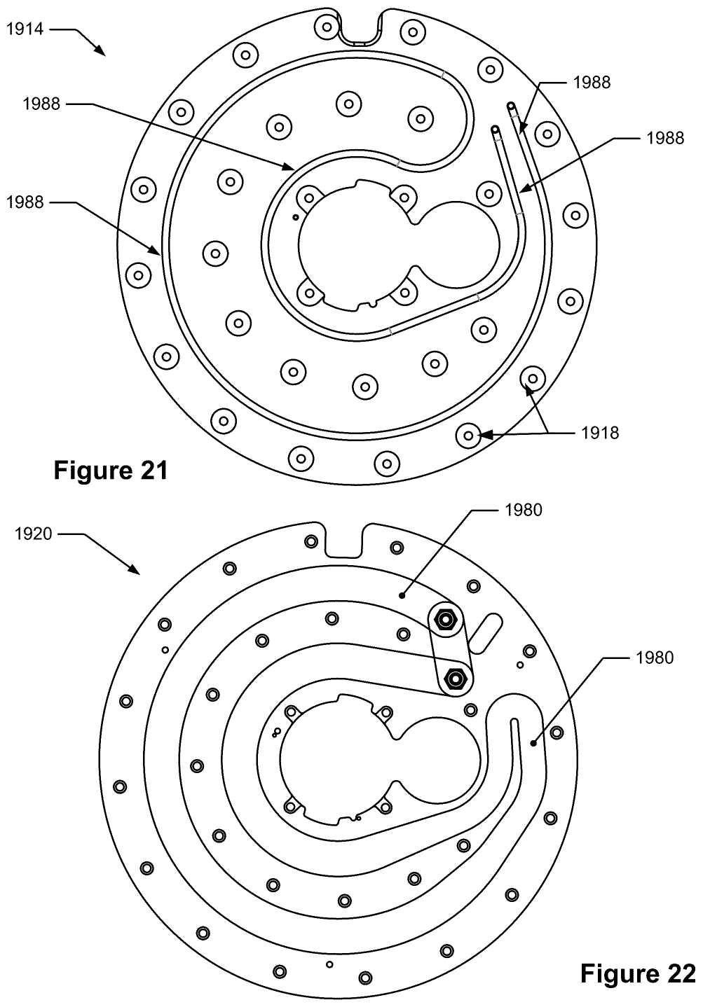

As discussed above, the gas distribution manifold 1906 of FIG. 19 may include heating plate assembly 1914. FIG. 21 shows a top view of an example of the heating plate assembly 1914 of the gas distribution manifold 1906 of FIG. 19, in accordance with some implementations. The heating plate assembly 1914 may include, for example, a heating plate such as a standard aluminum plate which may conduct heat. Heat may be provided to the plate by a resistive heating element 1988 that is either embedded within or placed in close thermal contact with the plate, such as by being pressed into a meandering groove that has been machined into the plate, as shown. For instance, the resistive heating element 1988 may have a metallic outer sheath with an internal insulator (such as magnesium oxide) separating a resistive component, such as a coil of nichrome wire, from the sheath. The heat provided to the heating plate assembly 1914 may be varied by supplying a varying electrical current through the resistive heating element 1988. This heating plate assembly 1914 is configured to heat the faceplate assembly 108.

The gas distribution manifold 1906 of FIG. 19 may include the cooling plate assembly 1920. FIG. 22 shows a top view of an example of the cooling plate assembly 1920 of the gas distribution manifold 1906 of FIG. 19, in accordance with some implementations. The cooling plate assembly 1920 may include cooling passages 1980. A cooling liquid such as water may be flowed through the cooling passages 1980 to providing thermal control to the faceplate assembly 1908. By way of example, cooling water having a temperature in ranging from 15 to 30 degrees Celsius may be flowed through the cooling passages 1980 to maintain a temperature of the faceplate assembly 1908 in the range of 200 to 300 degrees Celsius. Alternatively, such cooling may be accomplished using a high-temperature-compatible heat transfer fluid such as Galden®.

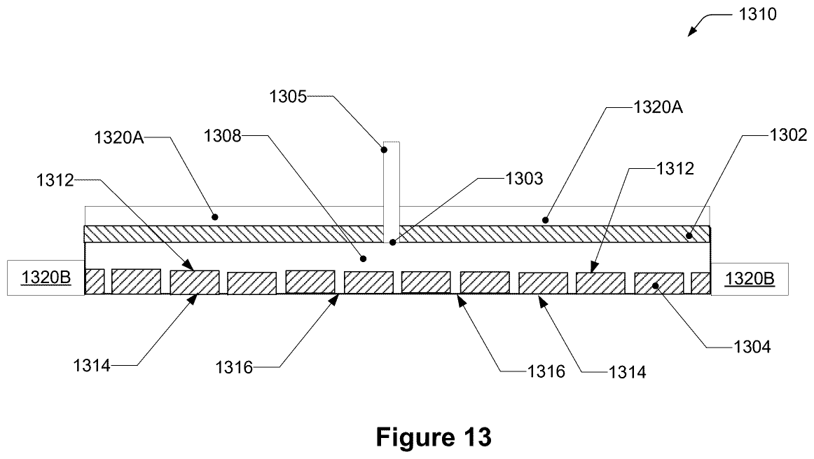

Some flush-mount showerheads may be constructed similarly to some chandelier-type showerheads. The flush-mount showerheads may have a backplate and a faceplate with through-holes that together form an internal plenum volume; the backplate, the faceplate, and/or the gas inlet to the backplate may be heated to control the flow conductance through the showerhead. FIG. 13 depicts a cross-sectional side view of an example flush-mount showerhead. Here, the flush-mount showerhead 1310 includes a back plate 1302 with a plenum inlet 1303, and a faceplate 1304 connected to the back plate 1302. The gas inlet 1305 of the showerhead 1310 may be considered the point where gas flows into the showerhead 1310; this gas inlet 1305 may be considered the gas inlet described herein, such as the gas inlet 112 and 212 of FIGS. 1, 2, and 14. The back plate 1302 and faceplate 1304 together partially define a plenum volume 1308 within the showerhead 1310, and in some instances, a baffle plate (not shown) may be positioned within the plenum volume 1308. The back plate 1302 and the faceplate 1304 may be positioned opposite one another within the showerhead such that they have surfaces that face each other. The faceplate 1304 includes a back surface 1312 that partially defines the plenum volume 1308 and faces the back plate 1302, and a front surface 1314 that is configured to face a substrate positioned when installed within the processing chamber. The faceplate 1304 also includes a plurality of through-holes 1316 (two are identified in FIG. 13) that extend through the faceplate 1304 from the back surface 1312 to the front surface 1314 and allow fluid to travel from the plenum volume 1308 to outside of the showerhead 1310 and onto a substrate.

The flush-mount showerheads may also include one or more temperature control units to control the temperature of one or more aspects, and thus adjust the flow conductance, of the showerhead. The showerhead of FIG. 13 includes illustrative examples of temperature control units that may be used to control a showerhead's temperature. In some embodiments, the showerhead 1310 may include one or more temperature control units 1320A configured to control the temperature of the back plate 1302. In some instances, controlling the temperature of the back plate 1302 may change the flow conductance within the plenum volume 1308 upstream from the showerhead's restrictive through-holes 1316 and thus provide more accurate and uniform flow conductance control and adjustment through the showerhead. The temperature control unit 1320A may be a single unit or a plurality of units. The temperature control unit 1320A may include one or more resistive heaters positioned on and/or within the back plate 1302, one or more fluid conduits positioned on or within the back plate 1302 and configured to flow heat transfer fluid, such as heated water, in order to heat the stem, or one or more cartridge heaters positioned in holes in the back plate 1302.

In some embodiments, the temperature control unit 1320A may also include one or more cooling elements configured to actively cool the back plate 1302, such as one or more fluid conduits positioned on or within the back plate 1302 and configured to flow heat transfer fluid, such as cooled water, and cool the back plate 1302. In some such embodiments, the temperature control unit 1320A may have two parts, with a first part as the heating part configured to heat the back plate 1302 and the second part as the cooling part configured to cool the back plate 1302. Each of these parts may include a sub-set of portions, such as the first part including multiple heating elements.

The faceplate 1304 of the showerhead 1310 may also include one or more temperature control units 1320B configured to heat, cool, or both, the faceplate 1304. These temperature control units 1320B may include one or more resistive heaters positioned within the faceplate 1304, in direct contact with the faceplate 1304, and/or thermally connected to the faceplate 1304 (and thus thermal energy is configured to travel directly between these items or indirectly through other thermally conductive material, such as a thermally conductive plate (e.g., that comprise a metal) that is interposed between the temperature control unit 1320B and the faceplate 1304). Alternatively, or in addition, the temperature control units 1320B may include one or more fluid conduits positioned within or in thermal contact with the faceplate 1304 and configured to flow heat transfer fluid, such as heated water and/or cooled water, and heat and/or the faceplate 1304. An example temperature-controlled showerhead is described above and shown in FIGS. 19-22.

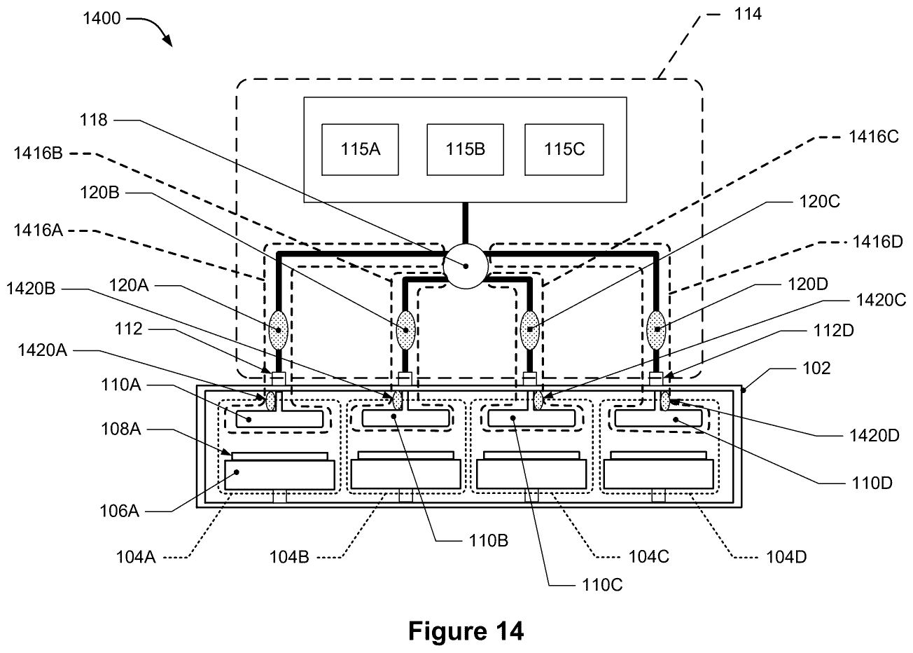

FIG. 14 depicts an example multi-station semiconductor processing tool 1400. This tool 1400 is the same as tool 100 in FIG. 1 and described herein, except that each flow path 1416A, 1416B, 1416C, and 1416D of tool 1400 includes the corresponding showerhead 110A, 110B, 110C, and 110D, respectively, of each corresponding processing station 104A, 104B, 104C, and 104D, respectively. For instance, flow path 1416A is fluidically connected to the processing station 104A and includes the showerhead 110A that is positioned within processing station 104A. These flow paths 1416A, 1416B, 1416C, and 1416D of tool 1400 may be considered to span between the junction point 118 and one or more aspects of the showerhead 110A, 110B, 110C, and 110D, respectively, thereby encompassing and extending past the gas inlets 112 of each showerhead. In some embodiments, the point where each flowpath ends in the showerhead may be considered at the fluidic connection between the showerhead and internal volume of the processing station, which may be considered the showerhead's gas distribution ports.

As also seen in FIG. 14, each showerhead 110A, 110B, 110C, and 110D includes one or more temperature control units represented by item 1420A, 1420B, 1420C, and 1420D, respectively. Each of these showerheads may be configured as described herein with respect to the showerhead 1210 of FIGS. 12A and 12B or showerhead 1310 of FIG. 13. For instance, the one or more temperature control units 1420A, 1420B, 1420C, and 1420D of showerheads 110A, 110B, 110C, and 110D may be those configured to control the temperature of the stem (e.g., 1220A), the faceplate (e.g., 1220B), or both. These one or more temperature control units 1420A, 1420B, 1420C, and 1420D of showerheads 110A, 110B, 110C, and 110D may therefore be used to control the flow conductance through the showerheads in the same manner as any other flow element described herein for any technique described herein. For instance, the flow elements of techniques described with respect to FIGS. 3-6 may be the showerheads of FIGS. 12A, 12B, 13, and 14.

### III. Example Techniques

The techniques and apparatuses herein utilize two or more flowpaths at different temperatures to adjust flow conductance through one flowpath, adjust the properties of deposited materials, and reduce station-to-station variations. In some embodiments, differences of a material property between stations can be reduced by adjusting the temperature of a flow element in one station's flowpath to thereby change the flow conductance and adjust the material property at that one station; this may be considered tuning the material property at that station. The temperature may also be adjusted during the deposition process to produce film properties having different values throughout the material. For example, the distance may be adjusted during the deposition to cause one section the material to have one value of a property and another section of the material, such as different values of RIs, within the material. In some embodiments, the temperature, and thus flow conductance, of a flow element may be adjusted so that it matches a desired flow conductance or a flow conductance of another flow element; this may be considered hardware tuning of that flow element. For instance, the flow conductance of a valve may be adjusted by changing its temperature so that valve matches, or substantially matches (e.g., is within +/−2%, +/−1%, or +/−0.5%) the flow conductance of another valve. Adjusting the temperature and flow conductance may be implemented in various ways.

Accordingly, in some embodiments, the temperatures of flow elements of two or more flowpaths may be different with respect to each other throughout deposition, including changing temperatures during deposition. This may include the temperatures (i) starting at different values than each other and remaining at those different values for the entirety of the deposition, (ii) starting at the same values as each other and then changing to different values later in the deposition process, (iii) starting at different values and then changing to the same value later in the deposition process, and (iv) starting at different values and then changing to other different values later in the deposition process. In some other embodiments, the temperatures may remain at the same value relative to each other throughout deposition, but may change their value throughout deposition.

A. Example Techniques with Temperatures at Different Values

In a first example technique, the temperatures of flow elements of two or more flowpaths are different with respect to each other during at least a portion of the deposition process to deposit one or more layers of material onto substrates. During this portion, one flow element of one flowpath is set to and maintained at a first temperature and another flow element of a second flowpath is set to and maintained at a second temperature. As used herein, a “layer” of material may be the total layer of material that is deposited after a complete deposition process which may include multiple sub-layers of material, and it may also include a single, discrete layer or sub-layer of material, such as a single discrete layer of material deposited by atomic layer deposition (ALD).

FIG. 3 depicts a first example technique for performing film deposition in a multi-station semiconductor processing chamber. The tool 100 of FIG. 1, processing stations 104A and 104B, and flowpaths 116A and 116B will be referenced to describe this technique. Even though the features of tool 100 of FIG. 1 are referenced, this technique is equally applicable to any other tool described herein, such as tool 200 of FIG. 2 and tool 1300 of FIG. 13 and any of the flow elements of flowpaths described herein including, for instance, a valve, a monoblock, one or more gas lines, a tee-fitting, a fitting, and a showerhead. These techniques may also be used to control the flow conductance through different flow elements, such as a valve in one flowpath and a monoblock in another flowpath. In block 301, the first substrate 108A is positioned onto the first pedestal 106A of the first station 104A, and in operation 303, the second substrate 108B is positioned onto the second pedestal 106B of the second station 104B. In some embodiments, blocks 301 and 303 may be performed in the reverse order or simultaneously.

Once these substrates are positioned on their respective pedestals, one or more layers of material may be simultaneously and individually deposited onto the first and second substrates, as represented by block 305. This may produce one or more first layer on the first substrate and one or more second layers on the second substrate. As described in more detail herein, a part of deposition processes generally involves flowing one or more process gases from the showerhead onto the substrate, for example, during a dose phase for ALD deposition, or during activation in chemical vapor deposition (CVD). These process gases are flowed to the substrates via the aforementioned flowpaths which may have flow elements set to different temperatures with respect to other flowpaths. As indicated in block 307, during at least a portion of the deposition one or more first and second layers on the first and second substrates, respectively, a first flow element of a first flowpath, like 116A, may be maintained at a first temperature while a second flow element of a second flowpath, like 116B, may be simultaneously maintained at a second temperature different than the first temperature. In some embodiments, the maintenance of a temperature may be an active heating of a flow element, such as by a resistive heater generating heat. In some other embodiments, the maintenance of a temperature may be the lack of heating, or not heating, the flow element, such that the temperature control unit is not actively heating the flow element; the flow element may therefore remain at the temperature of the ambient environment surrounding that flow element.

In some embodiments, these different temperatures may be maintained for the entirety of the deposition process required to deposit all of the desired layers of material. For example, if an ALD process is to perform 500 cycles, then these first and second temperatures may be maintained consistently throughout all of these 500 cycles. This temperature adjustment and setting may be made before the deposition process begins, or during some start-up operations, for instance. These operations may include substrate loading, temperature soak of the substrates (they are heated), indexing, and filling an ampoule.

In some instances, maintaining flowpaths with flow elements at different temperatures for the entirety of the deposition may produce layers of material at different stations that have the substantially same characteristics as each other, such as thickness and RI (substantially the same means within, e.g., 10%, 5%, 1%, 0.5%, or 0.1% of each other). This may result in better station-to-station matching. For instance, if it is determined that the thickness between two stations does not match within a certain threshold from each other, then for subsequent deposition processes the temperature of a flow element in the flowpath for one of the stations may be adjusted to change the flow conductance and in turn change the deposited thickness at that station so the thicknesses between stations are closer together. In some other embodiments, the deposited layer(s) of material at each station may have different characteristics than each other, such as different thicknesses. This may still result in better matching for other material characteristics. For instance, the material properties may have different densities than each other, but still result in the same thickness (which may be due to other process conditions, such as deposition rate).

For some embodiments, the different flow element temperatures of different flowpaths may be maintained for only a part of a deposition process in order to change the characteristics of only a part of the deposited material. Depositing layers on the same substrate with different characteristics may be advantageous for fine tuning the characteristics of just that one section (e.g., one layer or layers) of the overall deposited material. This may also be advantageous to adjust for drift of the process conditions or material properties during the processing of that substrate. For instance, as material is simultaneously deposited on a set of substrates at different stations, process conditions at one of the stations may drift during this processing, such as plasma power increasing or decreasing which in turn may result in layer(s) of the material having different material properties than other layers, such as different thicknesses, and result in station-to-station nonuniformity. Adjusting the flow conductance of one or more flowpaths during some of this processing may be able to adjust for the drifting process conditions and reduce the resulting nonuniformity. For example, if the plasma power of one station drifts during the course of processing which changes the thickness of deposited material, then the flow conductance of the flowpath for that station may be adjusted, by adjusting it temperature, to account for that drifted condition in order to produce a desired amount of material thickness at that station.

In another similar instance, process conditions may tend to drift throughout a batch of substrates (e.g., 200 or 500 substrates) and these drifting conditions may result in nonuniformity or increased nonuniformity of material properties, such as different thicknesses. Adjusting the flow conductance of one or more flowpaths during some of the batch of substrates may be able to adjust for the drifting process conditions and reduce the resulting nonuniformity. For example, if the plasma power of one station drifts during the course of processing the batch, e.g., after processing a particular number of substrates within the batch, then the deposited thickness at that station may drift beyond an acceptable threshold and the flow conductance of the flowpath for that station may be adjusted to account for that drifted condition in order to produce a desired amount of material thickness.

A batch of substrates may be defined as the number of substrates that may be processed for a particular deposition process before or when a limit is reached, such as an accumulation limit. For example, as material is deposited on multiple substrates, material from the deposition processes builds up on one or more interior chamber surfaces (e.g., of the chamber walls, pedestal, and showerhead) which is referred to herein as “accumulation.” As multiple substrates are processed within the same chamber in between cleanings of that chamber, the accumulation increases as more substrates are processed. When the accumulation in the chamber reaches a particular thickness, adverse effects may occur in the chamber, and when the accumulation reaches such a thickness, which may be referred to as the accumulation limit, the processing of substrates is stopped and the chamber is cleaned. In such an example, an ALD process in a particular chamber may have an accumulation limit of 20,000 Å which is the point at which the accumulation on the chamber causes adverse effects on substrates processed in that chamber. Accordingly, a batch of substrates processed in that chamber is limited to the number of substrates that may be processed in that chamber before the accumulation limit of 20,000 Å is reached.

In a second example technique, the temperatures of the flow elements in different flowpaths may start at the same temperature as each other and then be adjusted to different temperatures later in the deposition process. Here, some deposition may occur while the two temperatures are the same, which may be without any heat applied by their respective temperature control units, or may be the same heated temperature above ambient, for instance. After this first portion of deposition, the temperatures of the flow elements of the different flowpaths may be adjusted including heating the first flow element to the first temperature and heating the second flow element to the second temperature. Following this adjustment, additional deposition is performed on the first and second substrates while the first flow element is maintained at the first temperature and the second flow element is maintained at the second temperature. As stated above, in some embodiments, only one of the flow elements may be actively heated while the other flow element is not heated. For instance, the first temperature of the first flow element may be reached and maintained by actively heating the flow element while no heat may be applied to the second flow element. Referring to FIG. 3, the first portion of the deposition and the flowpath adjustments may be considered to occur after blocks 301 and 303, and before blocks 305 and 307.

In a third example technique, similar to but reversed from the second example technique, the temperatures of the flow elements in different flowpaths may start at different temperatures than each other and then change to become the same temperature later in the deposition process. Here, the adjustment to the same temperatures may be made using active cooling, such as by a cooling fluid, passive cooling, or active heating. In some such embodiments, the temperature of one flow element may be adjusted so that it is the same as the temperature of the other flow element. In some other such embodiments, the temperatures of both flow elements may be adjusted to another, same temperature. Referring to FIG. 3, the flowpath adjustments and the later part of the deposition may be considered to occur after blocks 301-307.

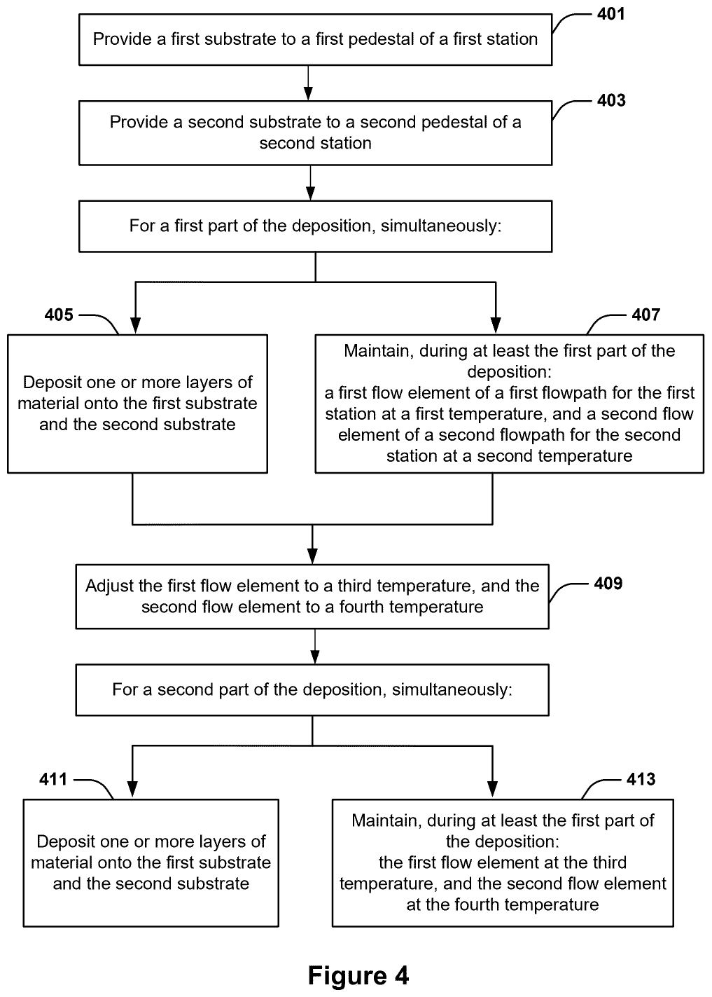

Similarly, a fourth example technique may include performing a first part of the simultaneous deposition on the substrates while the temperatures of the flow elements in different flowpaths are maintained at different temperatures than each other, and then performing another part of the simultaneous deposition while the temperatures of the flow elements in different flowpaths are maintained at other, different temperatures. FIG. 4 depicts the fourth technique for performing film deposition in a multi-station semiconductor processing chamber. Here, blocks 401 through 407 are the same as blocks 301 through 307 described above with respect to FIG. 3. Here in FIG. 4, blocks 401, 403, 405, and 407 are performed, and then after these blocks, in block 409 the temperature of first flow element is adjusted to a third temperature which is different than the first temperature, and the temperature of the second flow element is adjusted to a fourth temperature, which is different than the second temperature. After the flow elements are at these other, different temperatures, for a second part of the deposition another simultaneous deposition is performed on the two substrates in block 411 while the flow elements are maintained at these other, different temperatures.

In some embodiments, the temperature adjustment amount for each station may differ with respect to each station. For example, the first flow element may be adjusted from the first temperature by X degrees, while the second flow element may be adjusted from the second temperature by Y degrees. In some other embodiments, it may be desirable to maintain the flow elements at different temperatures from each other, but to adjust them by the same amount (e.g., adjusting both temperatures by X degrees). This may provide for uniform control and adjustment of properties to all of the substrates.

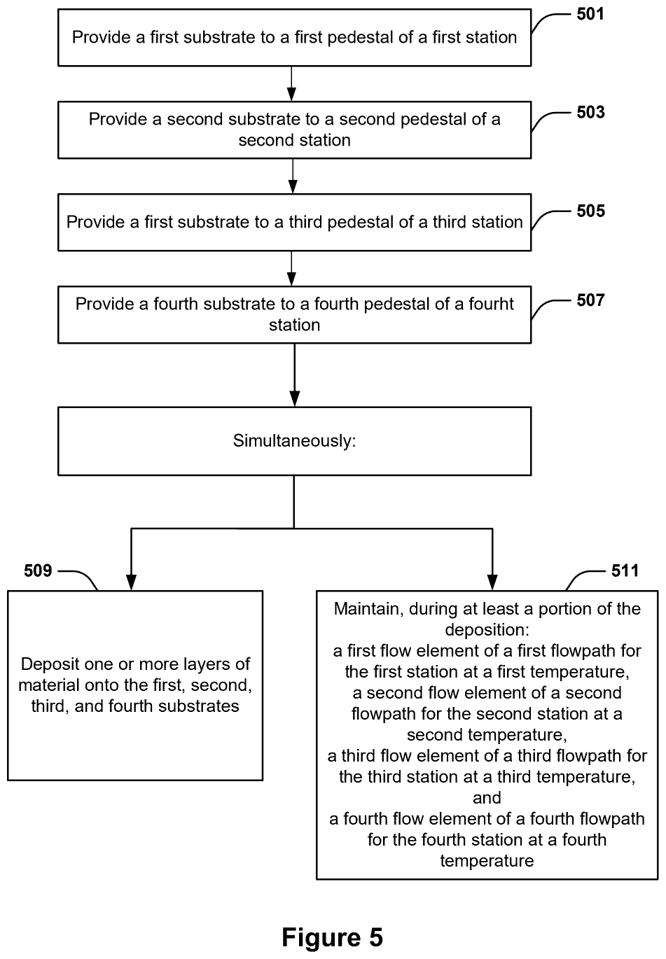

Additionally, although the techniques herein are described with respect to two flowpaths of two stations, these techniques are applicable to any number of multiple stations and flowpaths. For example, in a tool with a four-station chamber as shown in FIG. 1, the temperature of at least one flow element in each flowpath may be different than the corresponding flow elements in the other flowpaths. In some instances, as shown in FIG. 5 which depicts a fifth example technique for performing film deposition in a multi-station semiconductor processing chamber, for at least the first part of the deposition process in which one or more layers of material are simultaneously deposited on the four substrates in the four stations, 104A-104D, the first flow element of the first flowpath 116A may be at the first temperature, the second flow element of the second flowpath 116B may be at the second temperature, the third flow element of the third flowpath 116C may be at the third temperature, and the fourth flow element of the fourth flowpath 116D may be at the fourth temperature. In some embodiments, at least two of these temperatures may be different from each other and the other temperatures may be the same or different. For instance, all the temperatures may be different from each other, the first and second may be different from each other while the third and the fourth are the same as the first or the second, or the first, second, and third may all be different from each other while the fourth is the same as any of the other temperatures.

The techniques described herein are also applicable to the temperature control of multiple flow elements within each flowpath. For example, two or more flow elements may be heated to different temperatures in order to produce the desired flow conductance through that flowpath. Referring to FIG. 2 for instance, this may include heating two or more flow elements 222, 224, 226, and 228 of each flowpath 216A-216D.

B. Example Techniques with the Same Temperatures

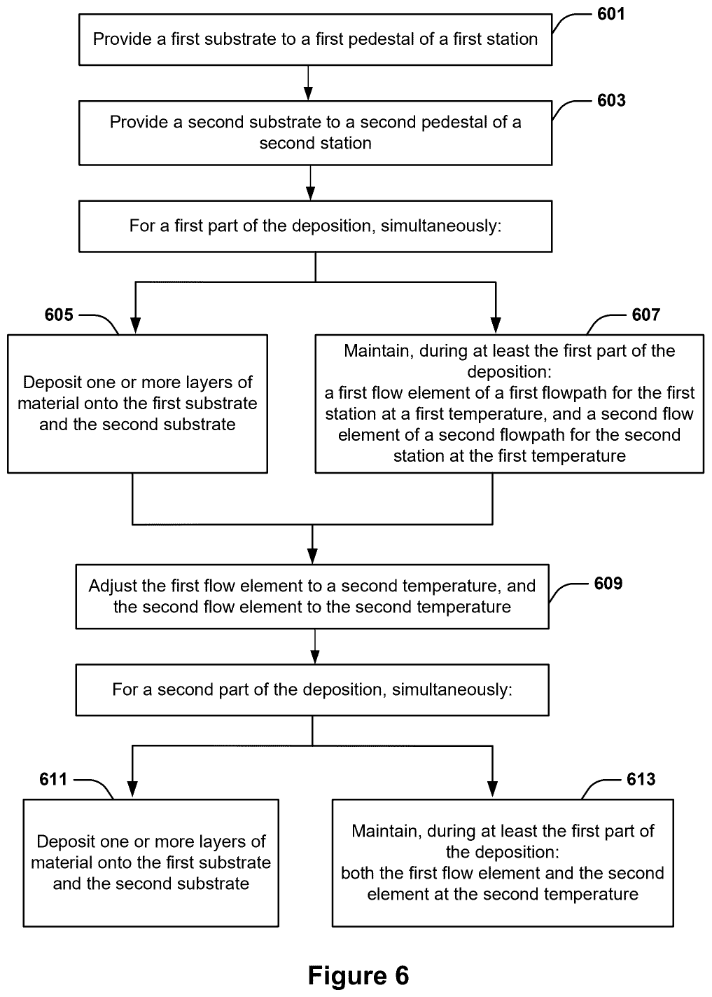

As stated above, the flow elements of different flowpaths may remain at the same temperature with respect to each other during the deposition, but are maintained at different temperatures during the deposition process with respect to a reference temperature. This concept is illustrated with FIG. 6 which depicts a sixth example technique for performing film deposition in a multi-station semiconductor processing chamber. Here, blocks 601 and 603 are the are the same as blocks 301 and 303 described above. For blocks 605 and 607, the first and second flow elements are both maintained at the same first temperature during simultaneous deposition of one or more layers of material onto the first and second substrates. In block 609, the first and second flow elements are both adjusted to the same second temperature, after which, in blocks 611 and 613, the first and second flow elements are both maintained at the same second temperature during simultaneous deposition of one or more layers of material onto the first and second substrates.

Here, the flow elements remain at the same temperature during the deposition process with respect to each other, but are at different distances with respect to the a reference temperature, such as the ambient environment of the tool. These embodiments may create a deposited material with different values of a property throughout the material. For instance, the deposited material on the first substrate has two different properties within the material, such as two different RIs. The distances may be adjusted additional times in order to create additional values and gradients within the deposited material.

C. Use of Example Techniques with Various Deposition Processes

All of the example techniques may be used in various deposition processes, such as CVD and ALD. For example, referring to FIG. 3, the simultaneous deposition and maintenance of the first and second temperatures of blocks 305 and 307 may be for the entire CVD or ALD deposition process for the first and second substrates. After this processing, post-processing operations may be performed and the substrates may be removed from the chamber. For cyclic deposition processes like ALD, the simultaneous deposition and maintenance of temperatures of blocks 305 and 307, 405 and 407, 411 and 413, 605 and 607, and 611 and 613 described above may be performed for one or more cycles of deposition such that these blocks may be repeated over a deposition process.

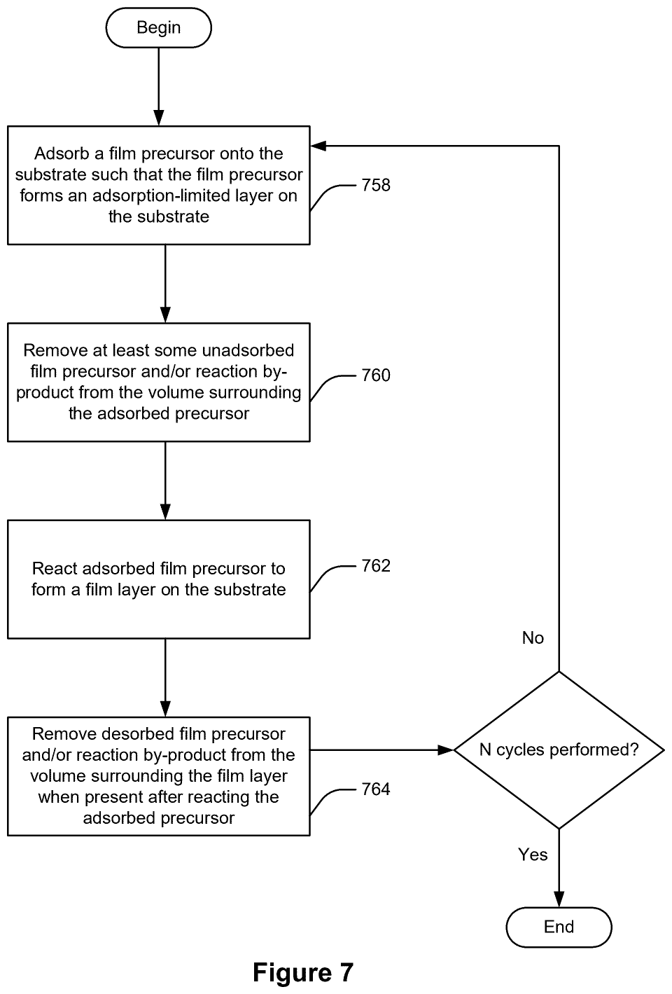

As stated above, a typical ALD cycle includes (1) exposure of the substrate surface to a first precursor, (2) purge of the reaction chamber in which the substrate is located, activation of a reaction of the substrate surface, typically with a plasma and/or a second precursor, and (4) purge of the reaction chamber in which the substrate is located. FIG. 7 depicts a flowchart of an example sequence of operations for forming a film of material on a substrate via an ALD process. As can be seen in FIG. 7, item 1 above corresponds with block 758, item 2 above corresponds with block 760, item 3 above corresponds with block 762, and item 4 above corresponds with block 764; the four blocks are performed for N cycles, after which the process is stopped.

In the techniques with multiple simultaneous deposition and temperature maintenance blocks, such as the example techniques of FIGS. 4 and 6, the overall deposition process may be split into two or more parts, with each part having a particular number of deposition cycles, and for the cycles of each part, those blocks associated with its respective part are performed. For instance, one part may have X cycles, another part may have Y cycles, and referring to FIG. 4, for instance, blocks 405 and 407 are performed for the X cycles such that the first and second temperatures are maintained and constant during all of the X cycles, then for the second part of deposition, the third and fourth temperatures are maintained and constant during all of the Y deposition cycles. All of the other example techniques may be similarly performed such that each simultaneous deposition and temperature blocks are performed for a particular number of deposition cycles in one part of the overall deposition process.

For all of the example techniques described herein, depending on the other processing conditions, the deposited layers of material simultaneously deposited on the substrates may be the same or may be different. For instance, they may have the same thickness or they may have a different density.

### D. Additional Techniques for Calibration

In some embodiments, calibration deposition processes may be performed in order to determine and associate flow element temperatures with different material property values. The calibration deposition processes may include positioning a first set of substrates at the stations, setting and maintaining the temperatures of a flow element in each flowpath for each station at a first temperature, simultaneously depositing material onto the first set of substrates, and then determining, such as by measuring, the resulting value of a material property, such as thickness and RI. Next, a second set of substrates may be loaded onto the pedestals, the temperatures of the flow elements may be set to and maintained at a second temperature, the deposition process may be repeated on the second set of substrates, and the resulting value of the material property may again be determined. This deposition and determination may be repeated for N sets of substrates at N different distances. The determined values of the material property for each station are associated with the temperatures of the flow elements at which the deposition occurred for that station and this information can be used in any of the above techniques in order to adjust a temperature and deposit a known value of a material property.

### IV. Experimental Results

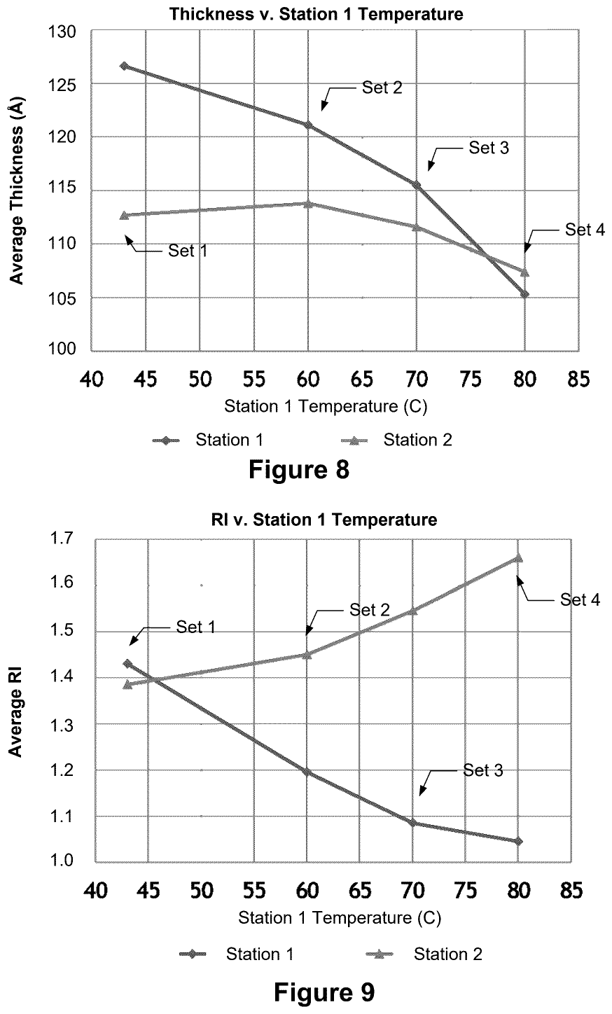

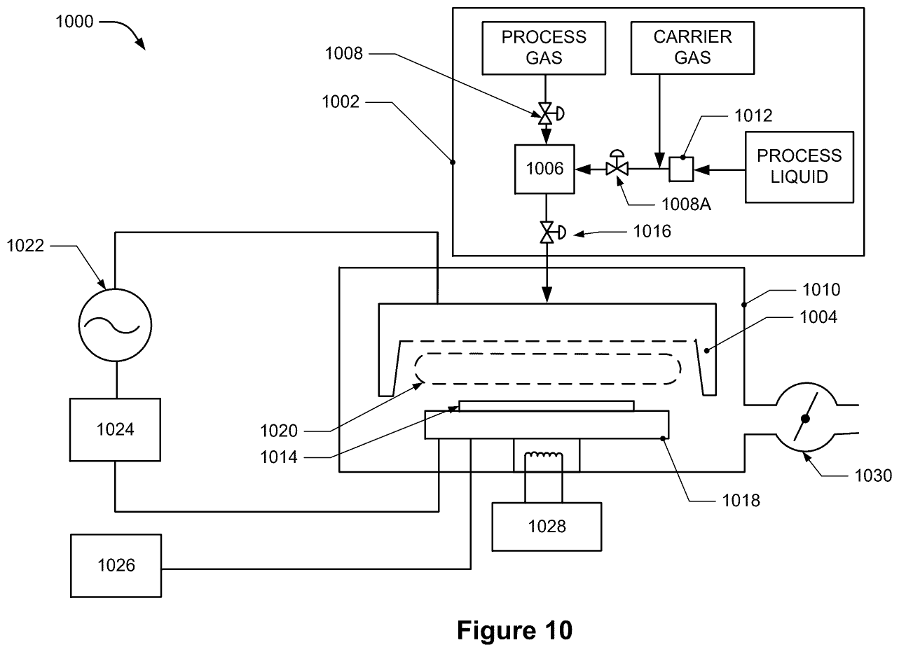

FIG. 8 depicts a plot of material thickness for two substrates. Here, four sets of two substrates were processed in a two-station chamber. For each set, one flow element, i.e., a gas line, in the flowpath of station 1 was heated to a different temperature for each set. The measured average thickness of material on the total 8 substrates is shown in FIG. 8; the horizontal axis is the temperature, in Celsius, of the gas line and the vertical axis is the average thickness of deposited material on the substrates. As can be seen, the overall thickness of deposited material decreased as the temperature of the flow element for station 1 increased. For instance, set 1 has the lowest temperature of about 42.5 C and the largest thickness of approximately 127 Angstroms (Å); this first set also has the largest thickness nonuniformity between the two stations. In set 4, with the flow element at the highest temperature of about 80 C, the station 1 thickness is the lowest at about 117 Å; this fourth set also has the smallest nonuniformity between the two stations. According to these results, thickness nonuniformity may be reduced by increasing the temperature of one flow element in one station's flowpath. Although no flow elements were heated for the flow path of station 1, the deposit thickness is seen changing during different sets of substrates. Despite this, this Figure illustrates that the thickness difference between each station may be adjusted by adjusting the temperature of at least one flow element of one station. This trend of station 1 may be caused by other varying conditions in processing chamber or process parameters. In some instances, this may be offset by a constant offset in flowrate or substrate temperatures. Alternatively or in addition, as FIG. 10 illustrates, station-to-station nonuniformity may be reduced by increasing the temperature of at least one flow element in one station's flowpath.

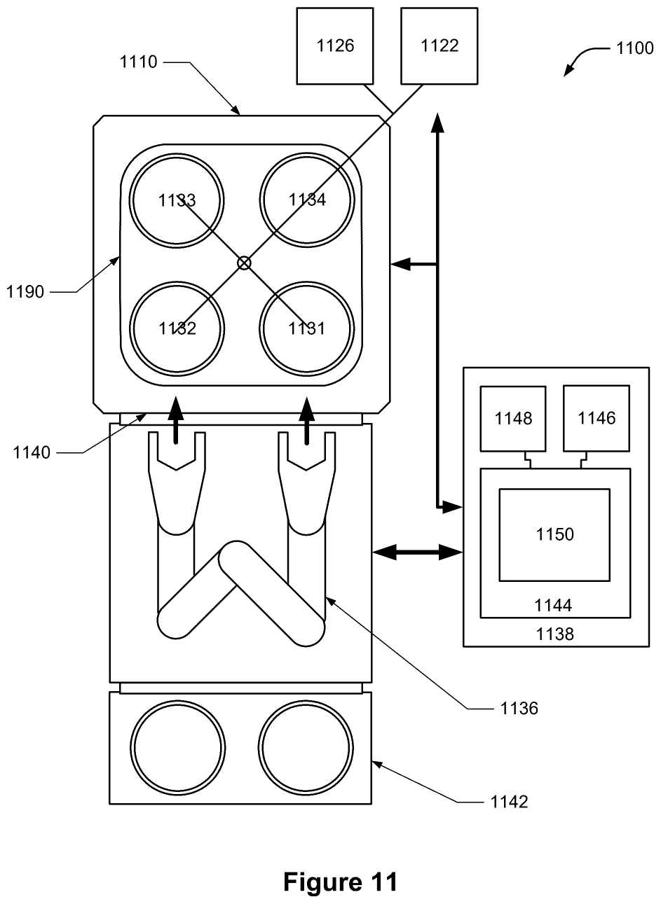

In another similar experiment, RI was measured and compared to different flow element temperatures. FIG. 9 depicts a plot of refractive index (RI) for two substrates. Here, four sets of two substrates were processed in a two-station chamber. For each set, one flow element, i.e., a gas line, in the flowpath of station 1 was heated to a different temperature for each set. The measured RI of deposited material on the total 8 substrates is shown in FIG. 9; the horizontal axis is the temperature, in Celsius, of the gas line and the vertical axis is the average RI of deposited material on the substrates. As can be seen, in contrast with the thickness seen in FIG. 8, the RI increases as the temperature of the flow element for station 1 increases. For instance, set 1 has the lowest temperature of about 42.5 C and the smallest RI of approximately 1.45; this first set also has the smallest RI nonuniformity between the two stations. In set 4, with the flow element at the highest temperature of about 80 C, the station 1 RI is the highest at about 1.65; this fourth set has the largest nonuniformity between the two stations. According to these results, RI nonuniformity may be reduced by reducing the temperature of one flow element in one station's flowpath. Additionally, even though the material deposited in station 1 in FIG. 11 decreases in RI for each of the sets of substrates and the increased temperature, this Figure illustrates that the difference between each station may be adjusted by adjusting the temperature of at least one flow element of one station. The trend of station 1 illustrated in FIG. 11 may be the result of each unit flowrate that is reduced from station 2 is taken by the remaining stations, such as station 1, because the total flowrate may be controlled by a single sources, like a single MFC. Accordingly, if all other conditions are held constant, then a reduction in a parameter for station 2, which is controlled by heating, may show a reduced, opposite direction effect then in the remaining stations.

### V. Additional Example Apparatuses

In some embodiments, a semiconductor processing tool or apparatus may have a controller, described in more detail below, with program instructions for executing any and all of the example techniques described herein. For example, the tools of FIGS. 1 and 2 may have additional features such as the controller for performing the example techniques. This includes controlling the temperature control units which are configured to be controllable. The controller may have program instructions to control the apparatus to deposit material onto the substrates at the stations, including executing the techniques described above. This may include providing a first substrate onto the first pedestal of the first station (e.g., station 104A), providing a second substrate onto a second pedestal of the second station (e.g., station 104B), simultaneously depositing one or more first layers of material onto the first substrate and one or more second layers of material onto the second substrate, while maintaining, during at least a portion of the simultaneous depositing, a first flow element of the first flowpath (e.g., 116A) for that first station at a first temperature, and a second flow element of the second flowpath (e.g., 116B) for that second station at a second temperature different than the first temperature.

Each of the tools or apparatuses may include additional features described herein. FIG. 10 depicts a single-station substrate processing apparatus for depositing films on semiconductor substrates using any number of processes. The apparatus 1000 of FIG. 10 has a single processing chamber 1010 with a single substrate holder 1018 (e.g., a pedestal) in an interior volume which may be maintained under vacuum by vacuum pump 1030. Also fluidically coupled to the chamber for the delivery of (for example) film precursors, carrier and/or purge and/or process gases, secondary reactants, etc. is gas delivery system 1002 and showerhead 1004. Equipment for generating a plasma within the processing chamber is also shown in FIG. 10. The apparatus schematically illustrated in FIG. 10 is commonly for performing ALD, although it may be adapted for performing other film deposition operations such as conventional CVD, particularly plasma enhanced CVD.

For simplicity, processing apparatus 1000 is depicted as a standalone process station having a process chamber body 1010 for maintaining a low-pressure environment. However, it will be appreciated that a plurality of process stations may be included in a common process tool environment—e.g., within a common reaction chamber—as described herein. For example, FIG. 11 depicts an implementation of a multi-station processing tool and is discussed in further detail below. Further, it will be appreciated that, in some implementations, one or more hardware parameters of processing apparatus 1000, including those discussed in detail herein, may be adjusted programmatically by one or more system controllers.

Process station 1010 fluidically communicates with gas delivery system 1002 for delivering process gases, which may include liquids and/or gases, to a distribution showerhead 1004. Gas delivery system 1002 includes a mixing vessel 1006 for blending and/or conditioning process gases for delivery to showerhead 1004. One or more mixing vessel inlet valves 1008 and 1008A may control introduction of process gases to mixing vessel 1006.

Some reactants may be stored in liquid form prior to vaporization and subsequent to delivery to the process chamber 1010. The implementation of FIG. 10 includes a vaporization point 1012 for vaporizing liquid reactant to be supplied to mixing vessel 1006. In some implementations, vaporization point 1012 may be a heated liquid injection module. In some other implementations, vaporization point 1012 may be a heated vaporizer. In yet other implementations, vaporization point 1012 may be eliminated from the process station. In some implementations, a liquid flow controller (LFC) upstream of vaporization point 1012 may be provided for controlling a mass flow of liquid for vaporization and delivery to processing chamber 1010.

As described above, showerhead 1004 distributes process gases and/or reactants (e.g., film precursors) toward substrate 1014 at the process station, the flow of which is controlled by one or more valves upstream from the showerhead (e.g., valves 1008, 1008A, and 1016). In the implementation shown in FIG. 10, substrate 1014 is located beneath showerhead 1004, and is shown resting on the pedestal 1018. Showerhead 1004 may have any suitable shape, and may have any suitable number and arrangement of ports for distributing processes gases to substrate 1014. In some implementations with two or more stations, the gas delivery system 1002 includes valves or other flow control structures upstream from the showerhead, which can independently control the flow of process gases and/or reactants to each station such that gas may be flowed to one station but not another. Furthermore, the gas delivery system 1002 may be configured to independently control the process gases and/or reactants delivered to each station in a multi-station apparatus such that the gas composition provided to different stations is different; e.g., the partial pressure of a gas component may vary between stations at the same time.

In FIG. 10, showerhead 1004 and pedestal 1018 are electrically connected to RF power supply 1022 and matching network 1024 for powering a plasma. In some implementations, the plasma energy may be controlled (e.g., via a system controller having appropriate machine-readable instructions and/or control logic) by controlling one or more of a process station pressure, a gas concentration, an RF source power, an RF source frequency, and a plasma power pulse timing. For example, RF power supply 1022 and matching network 1024 may be operated at any suitable power to form a plasma having a desired composition of radical species. Likewise, RF power supply 1022 may provide RF power of any suitable frequency and power. The apparatus 1000 also includes a DC power supply 1026 that is configured to provide a direct current to the pedestal, which may be an electrostatic chuck (“ESC”) 1018 in order to generate and provide an electrostatic clamping force to the ESC 1018 and the substrate 1014. The pedestal 1018 may also have one or more temperature control elements 1028 that are configured to heat and/or cool the substrate 1014. The pedestal 1018 is also configured to be raised and lowered to various heights, or distances, as measured between a pedestal surface and a showerhead.

In some implementations, the apparatus is controlled with appropriate hardware and/or appropriate machine-readable instructions in a system controller which may provide control instructions via a sequence of input/output control (IOC) instructions. In one example, the instructions for setting plasma conditions for plasma ignition or maintenance are provided in the form of a plasma activation recipe of a process recipe. In some cases, process recipes may be sequentially arranged, so that all instructions for a process are executed concurrently with that process. In some implementations, instructions for setting one or more plasma parameters may be included in a recipe preceding a plasma process. For example, a first recipe may include instructions for setting a flow rate of an inert (e.g., helium) and/or a reactant gas, instructions for setting a plasma generator to a power set point, and time delay instructions for the first recipe. A second, subsequent recipe may include instructions for enabling the plasma generator and time delay instructions for the second recipe. A third recipe may include instructions for disabling the plasma generator and time delay instructions for the third recipe. It will be appreciated that these recipes may be further subdivided and/or iterated in any suitable way within the scope of the present disclosure.

As described above, two or more process stations may be included in a multi-station substrate processing tool. FIG. 11 depicts an example multi-station substrate processing apparatus. Various efficiencies may be achieved through the use of a multi-station processing apparatus like that shown in FIG. 11 with respect to equipment cost, operational expenses, as well as increased throughput. For instance, a single vacuum pump may be used to create a single high-vacuum environment for all four process stations by evacuating spent process gases, etc. for all four process stations. Depending on the implementation, each process station may have its own dedicated showerhead for gas delivery, but may share the same gas delivery system. Likewise, certain elements of the plasma generator equipment may be shared amongst process stations (e.g., power supplies), although depending on the implementation, certain aspects may be process station-specific (for example, if showerheads are used to apply plasma-generating electrical potentials). Once again, it is to be understood that such efficiencies may also be achieved to a greater or lesser extent by using more or fewer numbers of process stations per processing chamber such as 2, 3, 5, 6, 7, 8, 9, 10, 11, 12, 13, 14, 15, or 16, or more process stations per reaction chamber.

The substrate processing apparatus 1100 of FIG. 11 employs a single substrate processing chamber 1110 that contains multiple substrate process stations, each of which may be used to perform processing operations on a substrate held in a wafer holder, e.g., a pedestal, at that process station. In this particular implementation, the multi-station substrate processing apparatus 1100 is shown having four process stations 1131, 1132, 1133, and 1134. Other similar multi-station processing apparatuses may have more or fewer processing stations depending on the implementation and, for instance, the desired level of parallel wafer processing, size/space constraints, cost constraints, etc. Also shown in FIG. 11 are a substrate handler robot 1136 and a controller 1138.

As shown in FIG. 11, the multi-station processing tool 1100 has a substrate loading port 1140, and a robot 1136 configured to move substrates from a cassette loaded through a pod 1142 through atmospheric port 1140, into the processing chamber 1110, and onto one of the four stations 1131, 1132, 1133, or 1134. These processing stations may be the same or similar to those of FIGS. 1 and 2.

The RF power is generated at an RF power system 1122 and distributed to each of the stations 1131, 1132, 1133, or 1134; similarly a DC power source 1126 is distributed to each of the station. The RF power system may include one or more RF power sources, e.g., a high frequency (HFRF) and a low frequency (LFRF) source, impedance matching modules, and filters. In certain implementations, the power source may be limited to only the high frequency or low frequency source. The distribution system of the RF power system may be symmetric about the reactor and may have high impedance. This symmetry and impedance result in approximately equal amounts of power being delivered to each station.

FIG. 11 also depicts an implementation of a substrate transferring device 1190 for transferring substrates between process stations 1131, 1132, 1133, and 1134 within processing chamber 1114. It will be appreciated that any suitable substrate transferring device may be employed. Non-limiting examples include wafer carousels and wafer handling robots.

FIG. 11 also depicts an implementation of a system controller 1138 employed to control process conditions and hardware states of process tool 1100 and its process stations. System controller 1138 may include one or more memory devices 1144, one or more mass storage devices 1146, and one or more processors 1148. Processor 1148 may include one or more CPUs, ASICs, general-purpose computer(s) and/or specific purpose computer(s), one or more analog and/or digital input/output connection(s), one or more stepper motor controller board(s), etc.

The system controller 1138 may execute machine-readable system control instructions 1150 on processor 1148 the system control instructions 1150, in some implementations, loaded into memory device 1144 from mass storage device 1146. System control instructions 1150 may include instructions for controlling the timing, mixture of gaseous and liquid reactants, chamber and/or station pressure, chamber and/or station temperature, wafer temperature, target power levels, RF power levels, RF exposure time, DC power and duration to clamp a substrate, substrate pedestal, chuck, and/or susceptor position, plasma formation in each station, flow of gaseous and liquid reactants, vertical height of the pedestal, and other parameters of a particular process performed by process tool 1100. These processes may include various types of processes including, but not limited to, processes related to deposition of film on substrates. System control instructions 1158 may be configured in any suitable way.

In some implementations, system control software 1158 may include input/output control (IOC) instructions for controlling the various parameters described above. For example, each step of a deposition process or processes may include one or more instructions for execution by system controller 1150. The instructions for setting process conditions for a primary film deposition process, for example, may be included in a corresponding deposition recipe, and likewise for a capping film deposition. In some implementations, the recipes may be sequentially arranged, so that all instructions for a process are executed concurrently with that process.

Other computer-readable instructions and/or programs stored on mass storage device 1154 and/or memory device 1156 associated with system controller 1150 may be employed in some implementations. Examples of programs or sections of programs include a substrate positioning program, a process gas control program, a pressure control program, a heater control program, and a plasma control program.

In some implementations, there may be a user interface associated with system controller 1150. The user interface may include a display screen, graphical software displays of the apparatus and/or process conditions, and user input devices such as pointing devices, keyboards, touch screens, microphones, etc.

In some implementations, parameters adjusted by system controller 1150 relate to process conditions. Non-limiting examples include process gas compositions and flow rates, temperatures, pressures, plasma conditions (such as RF bias power levels, frequencies, exposure times), etc. Additionally, the controller may be configured to independently control conditions in the process stations, e.g., the controller provides instructions to ignite a plasma in some but not all stations. These parameters may be provided to the user in the form of a recipe, which may be entered utilizing the user interface.

Signals for monitoring the processes may be provided by analog and/or digital input connections of system controller 1150 from various process tool sensors. The signals for controlling the processes may be output on the analog and/or digital output connections of process tool 1100. Non-limiting examples of process tool sensors that may be monitored include mass flow controllers (MFCs), pressure sensors (such as manometers), thermocouples, load sensors, OES sensors, metrology equipment for measuring physical characteristics of wavers in-situ, etc. Appropriately programmed feedback and control algorithms may be used with data from these sensors to maintain process conditions.

System controller 1150 may provide machine-readable instructions for implementing deposition processes. The instructions may control a variety of process parameters, such as DC power level, RF bias power level, station-to-station variations such as RF power parameter variations, frequency tuning parameters, pressure, temperature, etc. The instructions may control the parameters to operate in-situ deposition of film stacks according to various implementations described herein.

The system controller will typically include one or more memory devices and one or more processors configured to execute machine-readable instructions so that the apparatus will perform operations in accordance with the processes disclosed herein. Machine-readable, non-transitory media containing instructions for controlling operations in accordance with the substrate doping processes disclosed herein may be coupled to the system controller.

As mentioned above, processing multiple substrates at multiple process stations within a common substrate processing chamber may increase throughput by enabling film deposition to proceed in parallel on multiple substrates while at the same time utilizing common processing equipment between the various stations. Some multi-station substrate processing tools may be utilized to simultaneously process wafers for an equal number of cycles (e.g., for some ALD processes). Given this configuration of process stations and substrate loading and transferring devices, a variety of process sequences are possible which allow film deposition—say, for instance, N cycles of film deposition for an ALD process or an equal exposure duration for a CVD process—to occur in parallel (e.g., simultaneously) across multiple substrates.

As discussed above, various efficiencies may be achieved through the use of a multi-station tool with respect to equipment cost, operational expenses, as well as increased throughput. However, simultaneously processing multiple substrates in a common chamber can result in station-to-station differences of the deposited material, including, for example, differences in average film thickness, uniformity over the face of wafer, physical properties such as wet etch rate (WER) and dry etch rate (DER), chemical properties, and optical properties. There may be various thresholds of acceptable station-to-station deviations of material properties, but it is desirable to reduce these differences in order to repeatedly produce uniform substrates for commercial scale manufacturing. The techniques described herein may adjust one or more of these properties, such as a wet etch rate, a dry etch rate, a composition, a thickness, a density, an amount of cross-linking, a chemistry, a reaction completion, a stress, a refractive index, a dielectric constant, a hardness, an etch selectivity, a stability, and a hermeticity.

Although the above disclosure has focused on adjusting the flow conductance to control deposition parameters, the same control may be used to control etch characteristics in an etch process. Some semiconductor fabrication processes involve patterning and etching of various materials, including conductors, semiconductors, and dielectrics. Some examples include conductors, such as metals or carbon; semiconductors, such as silicon or germanium; and dielectrics, such as silicon oxide, aluminum dioxide, zirconium dioxide, hafnium dioxide, silicon nitride, and titanium nitride. Atomic layer etching (“ALE”) processes remove thin layers of material using sequential self-limiting reactions. Generally, an ALE cycle is the minimum set of operations used to perform an etch process one time, such as etching a monolayer. The result of one ALE cycle is that at least some of a film layer on a substrate surface is etched. Typically, an ALE cycle includes a modification operation to form a reactive layer, followed by a removal operation to remove or etch only this reactive layer. The cycle may include certain ancillary operations such as removing one of the reactants or byproducts. Generally, a cycle contains one instance of a unique sequence of operations.

As an example, a conventional ALE cycle may include the following operations: (i) delivery of a reactant gas, (ii) purging of the reactant gas from the chamber, (iii) delivery of a removal gas and an optional plasma, and (iv) purging of the chamber. In some embodiments, etching may be performed nonconformally. The modification operation generally forms a thin, reactive surface layer with a thickness less than the un-modified material. In an example modification operation, a substrate may be chlorinated by introducing chlorine into the chamber. Chlorine is used as an example etchant species or etching gas, but it will be understood that a different etching gas may be introduced into the chamber. The etching gas may be selected depending on the type and chemistry of the substrate to be etched. A plasma may be ignited and chlorine reacts with the substrate for the etching process; the chlorine may react with the substrate or may be adsorbed onto the surface of the substrate. The species generated from a chlorine plasma can be generated directly by forming a plasma in the process chamber housing the substrate or they can be generated remotely in a process chamber that does not house the substrate, and can be supplied into the process chamber housing the substrate.

Accordingly, any of the above techniques and apparatuses may be used for etching. In some embodiments, instead of depositing a layer of material in each station, the techniques may remove a portion of material in each station. This may provide greater wafer-to-wafer uniformity in either etch or deposition processes. For example, in FIG. 3, block 305 may be an etching phase in which for a first part of the etching process, the simultaneous etching on the first and second substrates may be performed while the first and second flow elements of the first and second flowpaths, respectively, are maintained at the first and second temperatures, respectively, in order to remove first and second portions of material from the first and second substrates.

In the following description, numerous specific details are set forth in order to provide a thorough understanding of the presented concepts. The presented concepts may be practiced without some or all of these specific details. In other instances, well known process operations have not been described in detail so as to not unnecessarily obscure the described concepts. While some concepts will be described in conjunction with the specific embodiments, it will be understood that these embodiments are not intended to be limiting.

In this application, the terms “semiconductor wafer,” “wafer,” “substrate,” “wafer substrate,” and “partially fabricated integrated circuit” are used interchangeably. One of ordinary skill in the art would understand that the term “partially fabricated integrated circuit” can refer to a silicon wafer during any of many stages of integrated circuit fabrication thereon. A wafer or substrate used in the semiconductor device industry typically has a diameter of 200 mm, or 300 mm, or 450 mm. The following detailed description assumes the invention is implemented for use with such a wafer. However, the invention is not so limited. The work piece may be of various shapes, sizes, and materials. In addition to semiconductor wafers, other work pieces that may take advantage of this invention include various articles such as printed circuit boards, magnetic recording media, magnetic recording sensors, mirrors, optical elements, micro-mechanical devices and the like.

Unless the context of this disclosure clearly requires otherwise, throughout the description and the claims, the words “comprise,” “comprising,” and the like are to be construed in an inclusive sense as opposed to an exclusive or exhaustive sense; that is to say, in a sense of “including, but not limited to.” Words using the singular or plural number also generally include the plural or singular number respectively. Additionally, the words “herein,” “hereunder,” “above,” “below,” and words of similar import refer to this application as a whole and not to any particular layers of this application. When the word “or” is used in reference to a list of two or more items, that word covers all of the following interpretations of the word: any of the items in the list, all of the items in the list, and any combination of the items in the list. The term “implementation” refers to implementations of techniques and methods described herein, as well as to physical objects that embody the structures and/or incorporate the techniques and/or methods described herein. The term “substantially” herein, unless otherwise specified, means within 5% of the referenced value. For example, substantially perpendicular means within +/−5% of parallel.

It is also to be understood that any use of ordinal indicators, e.g., (a), (b), (c), . . . , herein is for organizational purposes only, and is not intended to convey any particular sequence or importance to the items associated with each ordinal indicator. There may nonetheless be instances in which some items associated with ordinal indicators may inherently require a particular sequence, e.g., “(a) obtain information regarding X, (b) determine Y based on the information regarding X, and (c) obtain information regarding Z”; in this example, (a) would need to be performed (b) since (b) relies on information obtained in (a)-(c), however, could be performed before or after either of (a) and/or (b).

It is to be understood that use of the word “each,” such as in the phrase “for each <item> of the one or more <items>” or “of each <item>,” if used herein, should be understood to be inclusive of both a single-item group and multiple-item groups, i.e., the phrase “for . . . each” is used in the sense that it is used in programming languages to refer to each item of whatever population of items is referenced. For example, if the population of items referenced is a single item, then “each” would refer to only that single item (despite the fact that dictionary definitions of “each” frequently define the term to refer to “every one of two or more things”) and would not imply that there must be at least two of those items. Similarly, when a selected item may have one or more sub-items and a selection of one of those sub-items is made, it will be understood that in the case where the selected item has one and only one sub-item, selection of that one sub-item is inherent in the selection of the item itself.

It will also be understood that references to multiple controllers that are configured, in aggregate, to perform various functions are intended to encompass situations in which only one of the controllers is configured to perform all of the functions disclosed or discussed, as well as situations in which the various controllers each perform subportions of the functionality discussed.

Various modifications to the implementations described in this disclosure may be readily apparent to those skilled in the art, and the generic principles defined herein may be applied to other implementations without departing from the spirit or scope of this disclosure. Thus, the claims are not intended to be limited to the implementations shown herein, but are to be accorded the widest scope consistent with this disclosure, the principles and the novel features disclosed herein.

Certain features that are described in this specification in the context of separate implementations also can be implemented in combination in a single implementation. Conversely, various features that are described in the context of a single implementation also can be implemented in multiple implementations separately or in any suitable sub-combination. Moreover, although features may be described above as acting in certain combinations and even initially claimed as such, one or more features from a claimed combination can in some cases be excised from the combination, and the claimed combination may be directed to a sub-combination or variation of a sub-combination.

Similarly, while operations are depicted in the drawings in a particular order, this should not be understood as requiring that such operations be performed in the particular order shown or in sequential order, or that all illustrated operations be performed, to achieve desirable results. Further, the drawings may schematically depict one more example processes in the form of a flow diagram. However, other operations that are not depicted can be incorporated in the example processes that are schematically illustrated. For example, one or more additional operations can be performed before, after, simultaneously, or between any of the illustrated operations. In certain circumstances, multitasking and parallel processing may be advantageous. Moreover, the separation of various system components in the implementations described above should not be understood as requiring such separation in all implementations, and it should be understood that the described program components and systems can generally be integrated together in a single software product or packaged into multiple software products. Additionally, other implementations are within the scope of the following claims. In some cases, the actions recited in the claims can be performed in a different order and still achieve desirable results.

What is claimed is:

1. A method of depositing material onto substrates in a multi-station deposition apparatus having a first station with a first showerhead and a second station with a second showerhead, the method comprising:
providing a first substrate onto a first pedestal of the first station;
providing a second substrate onto a second pedestal of the second station;
simultaneously depositing a first layer of material onto the first substrate and a second layer of material onto the second substrate; and
independently controlling, during at least a portion of the simultaneous depositing:
a first temperature of a first valve of a first flowpath, wherein the first flowpath fluidically connects a junction point to the first showerhead, and wherein a first temperature control unit is positioned on the first valve and controllable to change the temperature of the first valve, and
a second temperature of a second valve of a second flowpath, wherein the second flowpath fluidically connects the junction point to the second showerhead, wherein a second temperature control unit is positioned on the second valve and controllable to change the temperature of the first valve.

2. The method of claim 1, wherein the first temperature is different than the second temperature.

3. The method of claim 1, wherein:
controlling the first valve to be at the first temperature causes the first valve to be at a first flow conductance, and
controlling the second valve to be at the second temperature causes the second valve to be at a second flow conductance different than the first flow conductance.

4. The method of claim 3, wherein:
controlling the first valve to be at the first temperature further causes the first flowpath to have a first flowpath conductance, and
controlling the second valve to be at the second temperature further causes the second flowpath to have the first flowpath conductance.

5. The method of claim 3, wherein:
controlling the first valve to be at the first temperature further causes the first flowpath to have a first flowpath conductance, and
controlling the second valve to be at the second temperature further causes the second flowpath to have a second flowpath conductance different than the first flowpath conductance.

6. The method of claim 1, wherein:
controlling the first valve to be at the first temperature causes the first valve to be at a first flow conductance, and
controlling the second valve to be at the second temperature causes the second valve to be at the first flow conductance.

7. The method of claim 6, wherein:
controlling the first valve to be at the first temperature further causes the first flowpath to have a first flowpath conductance, and
controlling the second valve to be at the second temperature further causes the second flowpath to have the first flowpath conductance.

8. The method of claim 6, wherein:
controlling the first valve to be at the first temperature further causes the first flowpath to have a first flowpath conductance, and
controlling the second valve to be at the second temperature further causes the second flowpath to have a second flowpath conductance different than the first flowpath conductance.

9. The method of claim 1, wherein:
controlling the first valve to be at the first temperature causes the first flowpath to be at a first flowpath conductance, and
controlling the second valve to be at the second temperature causes the second flowpath to be at a second flowpath conductance different than the first flowpath conductance.

10. The method of claim 1, wherein:
controlling the first valve to be at the first temperature causes the first flowpath to be at a first flowpath conductance, and
controlling the second valve to be at the second temperature causes the second flowpath to be at the first flowpath conductance.

11. The method of claim 1, wherein:
the first flowpath further comprises a first monoblock having one or more flow components and a first monoblock temperature control unit positioned on the first monoblock and controllable to change the temperature of the first monoblock,
the second flowpath further comprises a second monoblock having one or more flow components and a second monoblock temperature control unit positioned on the second monoblock and controllable to change the temperature of the first monoblock,
the method further comprises independently controlling, during at least the portion of the simultaneous depositing:
a third temperature of the first monoblock, and
a fourth temperature of the second monoblock.

12. The method of claim 11, wherein:
the third temperature is different than the fourth temperature,
controlling the first monoblock to be at the third temperature causes the first monoblock to be at a first monoblock flow conductance, and
controlling the second monoblock to be at the fourth temperature causes the second monoblock to be at a second monoblock flow conductance different than the first monoblock flow conductance.

13. The method of claim 11, wherein:
the first temperature is the same as the third temperature,
the second temperature is the same as the fourth temperature,
controlling the first valve to be at the first temperature and the first monoblock to be at the third temperature further causes the first flowpath to have a first flowpath conductance, and
controlling the second valve to be at the second temperature and the second monoblock to be at the fourth temperature further causes the second flowpath to have the first flowpath conductance.

14. The method of claim 11, wherein:
the first temperature is the same as the third temperature,
the second temperature is the same as the fourth temperature,
controlling the first valve to be at the first temperature and the first monoblock to be at the third temperature further causes the first flowpath to have a first flowpath conductance, and
controlling the second valve to be at the second temperature and the second monoblock to be at the fourth temperature further causes the second flowpath to have a second flowpath conductance different than the first flowpath conductance.

15. The method of claim 11, further comprising independently controlling a first flowpath conductance of the first flowpath and a second flowpath conductance of the second flowpath during at least the portion of the simultaneous depositing by controlling the first temperature of the first valve, the second temperature of the second valve, the third temperature of the first monoblock, and the fourth temperature of the second monoblock.

16. The method of claim 1, further comprising independently controlling a first flowpath conductance of the first flowpath and a second flowpath conductance of the second flowpath during at least the portion of the simultaneous depositing by controlling the first temperature of the first valve and the second temperature of the second valve.

17. The method of claim 16, wherein:
the first temperature is different than the second temperature, and
the first flowpath conductance is different than the second flowpath conductance.

18. The method of claim 16, wherein:
the first temperature is different than the second temperature, and
the first flowpath conductance is the same as the second flowpath conductance.

19. The method of claim 16, wherein:
the first temperature is the same as the second temperature, and
the first flowpath conductance is different than the second flowpath conductance.

20. The method of claim 1, further comprising:
providing, before providing the first substrate and the second substrate, a third substrate onto the first pedestal;
providing, before providing the first substrate and the second substrate, a fourth substrate onto the second pedestal; and
simultaneously depositing a third layer of material onto the first substrate and a fourth layer of material onto the second substrate while not maintaining the first valve at the first temperature and not maintaining the second valve at the second temperature, wherein:
a first nonuniformity between a property of the first layer of material on the first substrate and the property of the second layer of material on the second substrate, is smaller than a second nonuniformity between the property of the third layer of material on the third substrate and the property of the fourth layer of material on the fourth substrate.
